(19) United States
(12) Patent Application Publication
(10) Pub. No.: US 2025/0349728 A1
(43) Pub. Date: Nov. 13, 2025

(54) ENHANCED REDISTRIBUTION VIA STRUCTURE FOR RELIABILITY IMPROVEMENT IN SEMICONDUCTOR DIE PACKAGING AND METHODS FOR FORMING THE SAME

(71) Applicant: Taiwan Semiconductor Manufacturing Company Limited, Hsinchu (TW)

(72) Inventors: Chia-Kuei Hsu, Hsinchu City (TW); Ming-Chih Yew, Hsinchu-City (TW); Chin-Hua Wang, New Taipei City (TW); Li-Ling Liao, Hsinchu City (TW); Shin-Puu Jeng, Po-Shan Village (TW)

(21) Appl. No.: 19/279,037

(22) Filed: Jul. 24, 2025

Related U.S. Application Data
(62) Division of application No. 17/830,522, filed on Jun. 2, 2022.

(51) Int. Cl. H01L 23/538; H01L 21/48; H01L 23/00; H01L 25/065; H01L 25/18

(52) U.S. Cl. CPC H01L 23/5383; H01L 21/4857; H01L 23/5381; H01L 23/5386; H01L 25/0652; H01L 25/18; H01L 24/16; H01L 24/17; H01L 24/32; H01L 24/33; H01L 24/73; H01L 24/92; H01L 2224/16145; H01L 2224/16227; H01L 2224/17181; H01L 2224/32145; H01L 2224/32225; H01L 2224/33181; H01L 2224/73204; H01L 2224/73253; H01L 2224/92125; H01L 2924/1432; H01L 2924/1433; H01L 2924/1437; H01L 2924/1816

(57) ABSTRACT

Methods and devices include a chip package structure, including a first semiconductor die, a second semiconductor die, a redistribution structure, and a first underfill material portion located between the redistribution structure and the first semiconductor die and the second semiconductor die. The redistribution structure includes a first redistribution structure portion physically and electrically connected to the first semiconductor die, a second redistribution structure portion physically and electrically connected to the second semiconductor die, and a dummy bump region positioned between and electrically isolated from the first redistribution structure portion and the second redistribution structure portion.

### RELATED APPLICATION

This application is a divisional of U.S. patent application Ser. No. 17/830,522 entitled “Enhanced Redistribution Via Structure for Reliability Improvement in Semiconductor Die Packaging and Methods for Forming the Same,” filed on Jun. 2, 2022, the entire contents of which is hereby incorporated by reference for all purposes.

### BACKGROUND

During various manufacturing processes and operation of a chip package, a difference in coefficient of thermal expansion (CTE) values between the substrate and various adjoined or proximate components and layers (e.g., underfill material portions, semiconductor dies, silicon bridge, redistribution dielectric layers, Cu material of redistribution via layers and redistribution wiring interconnect layers) may induce deformation (warpage) within the chip package. Material expansion and contraction due to changes in temperatures within the chip package may also induce deformation of structures. Any such deformation may be transmitted to, or rippled into, the redistribution structure, leading to strain concentration and further deformation within the system package especially with respect to the redistribution wiring interconnect layers and redistribution via layers. Excess strain on the redistribution wiring interconnect layer and redistribution via layers may cause breaks in electrical connections to the semiconductor dies, causing irreversible damage that may limit the function of the chip package or render the chip package inoperable.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a region of an exemplary structure that includes a first carrier substrate and redistribution structures according to an embodiment of the present disclosure.

FIG. 1B is a magnified view of the dummy bump region (DBR) outlined in FIG. 1A.

FIG. 1C is a top-down view of the magnified view of the DBR along the horizontal plane A-A′ of FIG. 1B.

FIG. 1D is a top-down view of the exemplary intermediate structure of FIG. 1A.

FIG. 2A is vertical cross-sectional view of a region of the exemplary intermediate structure after formation of redistribution-side metal pad structures according to an embodiment of the present disclosure.

FIG. 2B is a top-down view of the region of the exemplary intermediate structure of FIG. 2A.

FIG. 3A is a vertical cross-sectional view of a region the exemplary intermediate structure after attaching semiconductor dies according to an embodiment of the present disclosure.

FIG. 3B is a top-down view of the region of the exemplary intermediate structure of FIG. 3A.

FIG. 3C is a magnified vertical cross-sectional view of a high bandwidth memory die.

FIG. 4 is a vertical cross-sectional view of a region of the exemplary intermediate structure after formation of first underfill material portions.

FIG. 5A is a vertical cross-sectional view of a region of the exemplary intermediate structure after formation of an epoxy molding compound (EMC) matrix according to an embodiment of the present disclosure.

FIG. 5B is a top-down view of the region of the exemplary intermediate structure of FIG. 5A.

FIG. 6 is a vertical cross-sectional view of a region of the exemplary intermediate structure after attaching a second carrier substrate and detaching the first carrier substrate according to an embodiment of the present disclosure.

FIG. 7 is a vertical cross-sectional view of a region of the exemplary intermediate structure after formation of fan-out bonding pads according to an embodiment of the present disclosure.

FIG. 8 is a vertical cross-sectional view of a region of the exemplary intermediate structure after detaching the second carrier substrate according to an embodiment of the present disclosure.

FIG. 9 is a vertical cross-sectional view of a region of the exemplary intermediate structure during dicing of a redistribution substrate and the EMC matrix according to an embodiment of the present disclosure.

FIG. 10A is a vertical cross-sectional view of a fan-out package according to an embodiment of the present disclosure.

FIG. 10B is a horizontal cross-sectional view of the fan-out package along the horizontal plane B-B′ of FIG. 10A.

FIG. 11A is a vertical cross-sectional view of an exemplary intermediate structure after attaching a silicon bridge according to an embodiment of the present disclosure.

FIG. 11B is a three-dimensional perspective view of the outlined region X of the intermediate structure after attaching a silicon bridge in FIG. 11A according to an embodiment of the present disclosure.

FIG. 12 is a vertical cross-sectional view of the exemplary intermediate structure after formation of a bridge underfill material portion according to an embodiment of the present disclosure.

FIG. 13 is a vertical cross-sectional view of an exemplary intermediate structure after attaching the fan-out package to a package substrate according to an embodiment of the present disclosure.

FIG. 14 is a vertical cross-sectional view of the exemplary intermediate structure after formation of a second underfill material portion according to an embodiment of the present disclosure.

FIG. 15 is a vertical cross-sectional view of the exemplary intermediate structure after attaching a stabilization substrate according to an embodiment of the present disclosure.

FIG. 16 is a vertical cross-sectional view of the exemplary structure after the package substrate is attached to a printed circuit board (PCB) according to an embodiment of the present disclosure.

FIG. 17A is a magnified view of a first alternative configuration of the DBR outlined in FIG. 1A according to an embodiment of the present disclosure.

FIG. 17B is a top-down view of the magnified view of the DBR along the horizontal plane A-A′ of FIG. 17A according to an embodiment of the present disclosure.

FIG. 17C is a three-dimensional perspective view of the first alternative configuration of the outlined region X of an intermediate structure after attaching a silicon bridge in FIG. 11A according to an embodiment of the present disclosure.

FIG. 18A is a magnified view of a second alternative configuration of the DBR outlined in FIG. 1A according to an embodiment of the present disclosure.

FIG. 18B is a top-down view of the magnified view of the DBR along the horizontal plane A-A′ of FIG. 18A according to an embodiment of the present disclosure.

FIG. 18C is a three-dimensional perspective view of the second alternative configuration of the outlined region X of an intermediate structure after attaching a silicon bridge in FIG. 11A according to an embodiment of the present disclosure.

FIG. 19A is a magnified view of a third alternative configuration of the DBR outlined in FIG. 1A according to an embodiment of the present disclosure.

FIG. 19B is a top-down view of the magnified view of the DBR along the horizontal plane A-A′ of FIG. 19A according to an embodiment of the present disclosure.

FIG. 19C is a three-dimensional perspective view of the third alternative configuration of the outlined region X of an intermediate structure after attaching a silicon bridge in FIG. 11A according to an embodiment of the present disclosure.

FIG. 20A is a magnified view of a fourth alternative configuration of the DBR outlined in FIG. 1A according to an embodiment of the present disclosure.

FIG. 20B is a compounded top-down view of the magnified view of the DBR along the horizontal planes A-A′ and B-B′ of FIG. 20A according to an embodiment of the present disclosure.

FIG. 20C is a three-dimensional perspective view of the fourth alternative configuration of the outlined region X of an intermediate structure after attaching a silicon bridge in FIG. 11A according to an embodiment of the present disclosure.

FIG. 21A is a magnified view of a fifth alternative configuration of the DBR outlined in FIG. 1A according to an embodiment of the present disclosure.

FIG. 21B is a top-down view of the magnified view of the DBR along the horizontal plane A-A′ of FIG. 21A according to an embodiment of the present disclosure.

FIG. 21C is a three-dimensional perspective view of the fifth alternative configuration of the outlined region X of an intermediate structure after attaching a silicon bridge in FIG. 11A according to an embodiment of the present disclosure.

FIG. 22A is a magnified view of a sixth alternative configuration of the DBR outlined in FIG. 1A according to an embodiment of the present disclosure.

FIG. 22B is a top-down view of the magnified view of the DBR along the horizontal plane A-A′ of FIG. 22A according to an embodiment of the present disclosure.

FIG. 22C is a three-dimensional perspective view of the sixth alternative configuration of the outlined region X of an intermediate structure after attaching a silicon bridge in FIG. 11A according to an embodiment of the present disclosure.

FIG. 23A is a magnified view of a seventh alternative configuration of the DBR outlined in FIG. 1A according to an embodiment of the present disclosure.

FIG. 23B is a top-down view of the magnified view of the DBR along the horizontal plane A-A′ of FIG. 23A according to an embodiment of the present disclosure.

FIG. 23C is a three-dimensional perspective view of the seventh alternative configuration of the outlined region X of an intermediate structure after attaching a silicon bridge in FIG. 11A according to an embodiment of the present disclosure.

FIG. 24A is a magnified view of an eighth alternative configuration of the DBR outlined in FIG. 1A according to an embodiment of the present disclosure.

FIG. 24B is a top-down view of the magnified view of the DBR along the horizontal plane A-A′ of FIG. 24A according to an embodiment of the present disclosure.

FIG. 24C is a three-dimensional perspective view of the eighth alternative configuration of the outlined region X of an intermediate structure after attaching a silicon bridge in FIG. 11A according to an embodiment of the present disclosure.

FIG. 25A is a magnified view of a ninth alternative configuration of the DBR outlined in FIG. 1A according to an embodiment of the present disclosure.

FIG. 25B is a compounded top-down view of the magnified view of the DBR along the horizontal planes A-A′ and B-B′ of FIG. 25A according to an embodiment of the present disclosure.

FIG. 25C is a three-dimensional perspective view of the ninth alternative configuration of the outlined region X of an intermediate structure after attaching a silicon bridge in FIG. 11A according to an embodiment of the present disclosure.

FIG. 26 is a flowchart illustrating steps for forming an exemplary structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein may be directed to semiconductor devices, and particularly to redistribution structures including a dummy bump region (DBR). Generally, the various embodiment methods and structures disclosed herein may be used to provide an enhanced chip package structure such as a fan-out wafer level package (FOWLP) and fan-out panel level package (FOPLP). While the present disclosure is described using an FOWLP configuration, the methods and structures of the present disclosure may be implemented in an FOPLP configuration or any other package configuration, such as chip-on-wafer-on-substrate (CoWoS) packages or integrated fan-out (InFO) packages. The various embodiment chip package structures may have enhanced resistance to deformation within the redistribution structure.

Typically, heterogeneous integration is used to integrate a large interposer, or redistribution structure (such as a silicon interposer, CoWoS® interposer or an organic interposer) and a high electrical performance substrate (such as a multi-layer core or a multilayer substrate, which may include 12 or more layers) for a high-performance chip. The effective coefficient of thermal expansion (CTE) for such a structure may be more than four times (4×) the CTE for silicon. Such a large mismatch of CTE values between a substrate and semiconductor dies on a redistribution structure may result in significant mechanical strain on electrical connections including vias and wiring interconnects within the redistribution structure due to thermal expansion, deformation and warpage. Furthermore, material expansion and contraction due to changes in temperatures within the chip package may also induce deformation of structures. Any such deformation may be transmitted to, or rippled into, the redistribution structure, leading to strain concentration and further deformation within the chip package especially with respect to redistribution wiring interconnect layers and redistribution via layers. Excess strain on the redistribution wiring interconnect layers and redistribution dielectric layers may cause breaks in electrical connections to the attached semiconductor dies, causing irreversible damage that may limit the function of the chip package or may render the semiconductor package inoperable.

According to an aspect of the present disclosure, a DBR including enhanced vias and wiring interconnects that are electrically isolated from the semiconductor dies may be formed. The DBR within the redistribution structure may be formed between a first redistribution structure portion of the redistribution structure that is attached to a first semiconductor die and a second redistribution structure portion of the redistribution structure that is attached to a second semiconductor die. The reliability window of the chip package may be improved such that the deformation of signal redistribution layout (i.e., redistribution via layers and redistribution wiring interconnect layers of the first redistribution structure portion and the second redistribution structure portion) may be suppressed and strain is reduced. In other words, the DBR may act as an electrically-isolated stiffener that reduces the deformation of signal-carrying wiring interconnects of the redistribution structure caused by CTE mismatches and material expansion and contraction. Thus, various embodiment chip packages disclosed herein may be more resistant to strain and crack generation and/or crack propagation under thermal stress. The various disclosed embodiments provide a structure that may improve the reliability and reduce the stress on the connections within the redistribution structure and improve overall package reliability. The various embodiment methods and structures disclosed herein are now described with reference to accompanying drawings.

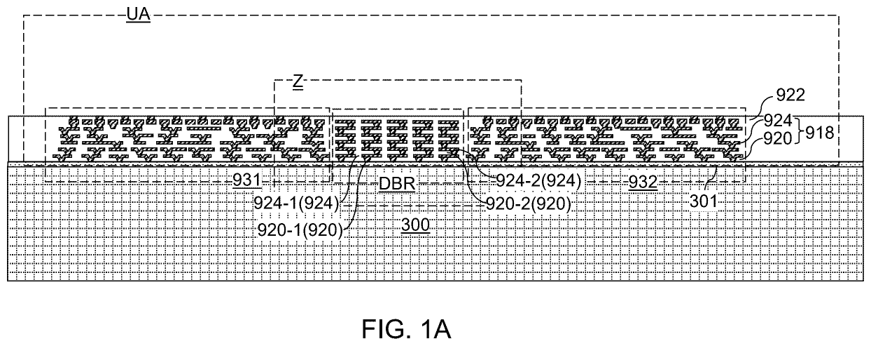

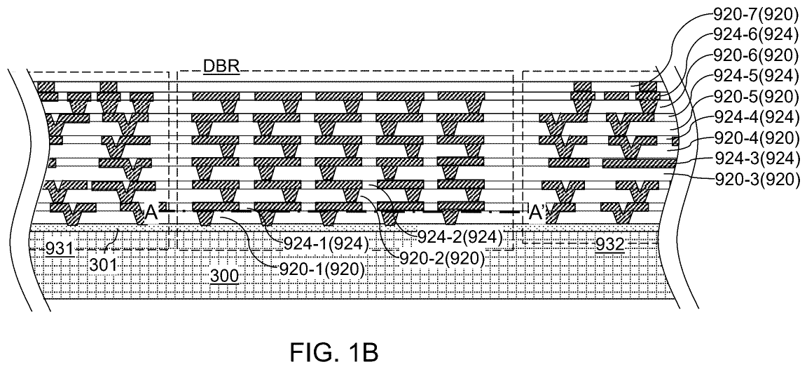

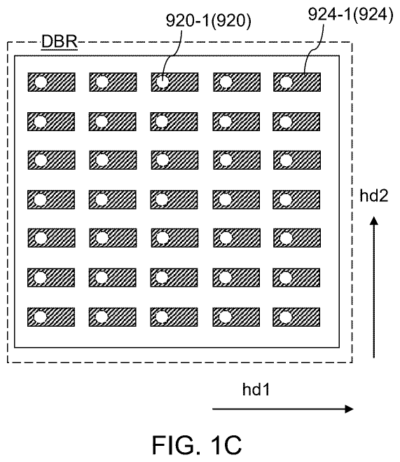

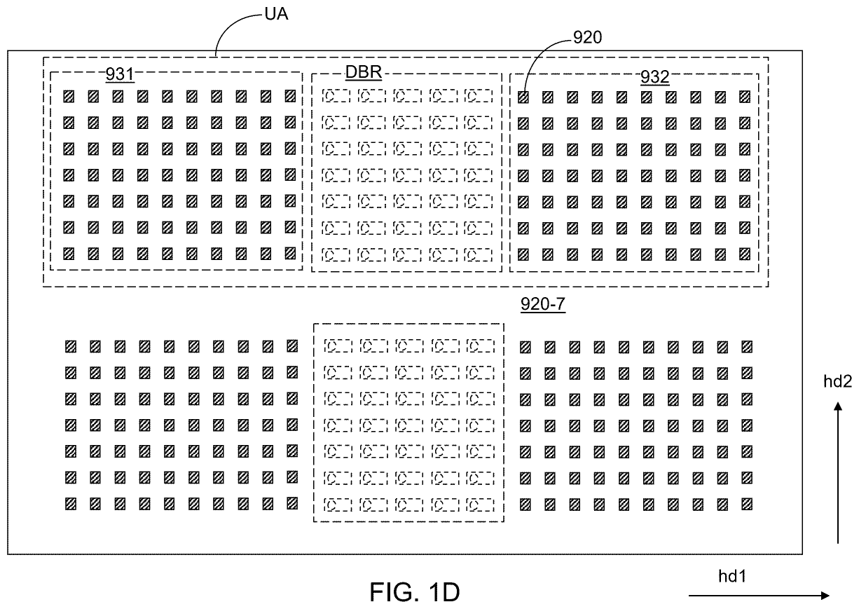

Referring to FIGS. 1A-1D, an exemplary structure according to an embodiment of the present disclosure may include a first carrier substrate 300 and redistribution structure 918 formed on a front side surface of the first carrier substrate 300. FIG. 1A is a vertical cross-sectional view of a region of an exemplary structure that includes a first carrier substrate and redistribution structures according to an embodiment of the present disclosure.

The redistribution structure 918 may be referred to as an interposer including various interposer layers. The first carrier substrate 300 may include an optically transparent substrate such as a glass substrate or a sapphire substrate. The diameter of the first carrier substrate 300 may be in a range from 150 mm to 290 mm, although lesser and greater diameters may be used. In addition, the thickness of the first carrier substrate 300 may be in a range from 500 microns to 2,000 microns, although lesser and greater thicknesses may also be used. Alternatively, the first carrier substrate 300 may be provided in a rectangular panel format.

A first adhesive layer 301 may be applied to the front-side surface of the first carrier substrate 300. In one embodiment, the first adhesive layer 301 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 301 may include a thermally decomposing adhesive material. For example, the first adhesive layer 301 may include an acrylic pressure-sensitive adhesive that decomposes at an elevated temperature. The debonding temperature of the thermally decomposing adhesive material may be in a range from 150 degrees to 200 degrees Celsius, although hotter or cooler debonding temperatures may be used.

Redistribution structures 918 may be formed over the first adhesive layer 301. Specifically, a redistribution structure 918 may be formed within each unit area UA, which is the area of a repetition unit that is repeated in a two-dimensional array over the first carrier substrate 300. Each redistribution structure 918 may include redistribution via layers 920 and redistribution wiring interconnect layers 924. The redistribution via layers 920 and the redistribution wiring interconnect layers 924 may include vias and wiring interconnects structures respectively, and the vias and wiring interconnect structures may be formed within redistribution dielectric material layers. The redistribution dielectric material layers may include a respective dielectric polymer material such as polyimide (PI), benzocyclobutene (BCB), or polybenzobisoxazole (PBO). Other suitable dielectric materials may be within the contemplated scope of disclosure. Each redistribution dielectric layer may be formed by spin coating and drying of the respective dielectric polymer material. The thickness of each redistribution dielectric layer may be in a range from 2 microns to 40 microns, such as from 4 microns to 20 microns. Each redistribution dielectric layer may be patterned, for example, by applying and patterning a respective photoresist layer thereabove, and by transferring the pattern in the photoresist layer into the redistribution dielectric layer using an etch process such as an anisotropic etch process. The photoresist layer may be subsequently removed, for example, by ashing.

Each of the redistribution via layers 920 and redistribution wiring interconnect layers 924 may be formed within the redistribution dielectric material layers by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 400 nm, and the copper seed layer may have a thickness in a range from 100 nm to 500 nm. The metallic fill material for the redistribution via layers 920 and redistribution wiring interconnect layers 924 may include copper, nickel, or copper and nickel. Other suitable metallic fill materials are within the contemplated scope of disclosure. The thickness of the metallic fill material that is deposited for each redistribution via layer 920 and redistribution wiring interconnect layer 924 may be in a range from 2 microns to 40 microns, such as from 4 microns to 10 microns, although lesser or greater thicknesses may also be used. The total number of levels of wiring in each redistribution structure 918 (i.e., levels of the redistribution via layers 920 and the redistribution wiring interconnect layers 924) may be in a range from 1 to 10. A periodic two-dimensional array (such as a rectangular array) of redistribution structures 918 may be formed over the first carrier substrate 300. Each redistribution structure 918 may be formed within a unit area UA, which is a unit of repetition for a two-dimensional array of redistribution structures 918. A layer including redistribution structures 918 (e.g., redistribution via layers 920 and redistribution wiring interconnect layers 924) is herein referred to as a redistribution structure layer. The redistribution structure layer includes a two-dimensional array of redistribution structures 918. In one embodiment, the two-dimensional array of redistribution structures 918 may be a rectangular periodic two-dimensional array of redistribution structures 918 having a first periodicity along a first horizontal direction hd1 and having a second periodicity along a second horizontal direction hd2 that is perpendicular to the first horizontal direction hd1.

Referring to FIG. 1B, a magnified view of the region Z outlined in FIG. 1A including the dummy bump region (DBR) and portions of a first redistribution structure portion 931 and a second redistribution structure portion 932 is illustrated. The redistribution structure 918 may include a number of alternating redistribution via layers 920 and redistribution wiring interconnect layers 924. For example, as illustrated in FIG. 1B, the redistribution structure 918 may include a first redistribution via layer 920-1, a first redistribution wiring interconnect layer 924-1, a second redistribution via layer 920-2, a second redistribution wiring interconnect layer 924-2, a third redistribution via layer 920-3, a third redistribution wiring interconnect layer 924-3, a fourth redistribution via layer 920-4, a fourth redistribution wiring interconnect layer 924-4, a fifth redistribution via layer 920-5, a fifth redistribution wiring interconnect layer 924-5, a sixth redistribution via layer 920-6, a sixth redistribution wiring interconnect layer 924-5, and a seventh redistribution via layer 920-7 formed in that order.

The DBR may be formed between a first redistribution structure portion 931 of the redistribution structure 918 and a second redistribution structure portion 932 of the redistribution structure 918 when forming the redistribution via layers 920 and the redistribution wiring interconnect layers 924 of the redistribution structure 918. The DBR may include redistribution via layers 920 and redistribution wiring interconnect layers 924 that may be formed in the same or similar way and/or simultaneously (i.e., during the same manufacturing processes at each layer) as the redistribution via layers 920 and redistribution wiring interconnect layers 924 of the first redistribution structure portion 931 and the second redistribution structure portion 932. In other words, the first redistribution via layer 920-1 may be formed within the DBR, the first redistribution structure portion 931, and the second redistribution structure portion 932, the first redistribution wiring interconnect layer 924-1 may be then formed within the DBR, the first redistribution structure portion 931, and the second redistribution structure portion 932 over the first redistribution via layer 920-1, the second redistribution via layer 920-2 may then be formed within the DBR, the first redistribution structure portion 931, and the second redistribution structure portion 932 over the first redistribution wiring interconnect layer 924-1, and so on.

The DBR may be capped with a redistribution via layer 920 (e.g., 920-7) that may electrically isolate the lower redistribution via layers 920 and the redistribution wiring interconnect layers 924 from any components that may subsequently be formed above the DBR with respect to the illustrated cross-sectional view. For example, the topmost via layer, seventh redistribution via layer 920-7, may be formed without vias within the DBR and with vias within the first redistribution structure portion 931 and the second redistribution structure portion 932, such that the topmost layer within the DBR may include only dielectric isolating material. In some embodiments, top surfaces of the vias of a topmost redistribution via layer 920 within the DBR may be exposed through and/or on a same horizontal plane as a topmost surface of the redistribution structure 918. For example, the topmost via layer, seventh redistribution via layer 920-7, may be formed to include vias within the DBR in addition to vias within the first redistribution structure portion 931 and the second redistribution structure portion 932, and top surfaces of the vias of the seventh redistribution via layer 920-7 may be exposed and on a same horizontal plane as a topmost surface of the redistribution structure 918. In some embodiments, the bottommost vias of the DBR included within the first redistribution via layer 920-1 may be electrically connected to a silicon bridge embedded within a substrate during subsequent manufacturing processes.

The redistribution via layers 920 of the DBR may include enhanced vias. In some embodiments, for each n number of redistribution wiring interconnect layers 924 within the redistribution structure 918, there may be n+1 number of redistribution via layers 920. For example, in embodiments in which a redistribution structure 918 includes six redistribution wiring interconnect layers 924 (e.g., 924-1-924-6), then the redistribution structure 918 may include seven redistribution via layers 920 (e.g., 920-1-920-7). In some embodiments, the number of redistribution wiring interconnect layers 924 may be equal to the number of redistribution via layers 920 within the redistribution structure 918. The redistribution structure 918, and therefore the DBR, the first redistribution structure portion 931, and the second redistribution structure portion 932, may include any number of redistribution via layers 920 and redistribution wiring interconnect layers 924 including the first redistribution via layer 920-1, the first redistribution wiring interconnect layer 924-1, the second redistribution via layer 920-2, the second redistribution wiring interconnect layer 924-2, and so on.

During various manufacturing processes and operation of a chip package, a difference in CTE values between the substrate and various adjoined or proximate components and layers (e.g., underfill material portions, semiconductor dies, silicon bridge, and dielectric material and Cu material of redistribution via layers 920 and redistribution wiring interconnect layers 924) may induce deformation within the system package. Material expansion and contraction due to changes in temperatures within the semiconductor package may also induce deformation of structures. Any such deformation may be transmitted to, or rippled into, the redistribution structure 918, leading to strain concentration and further deformation within the system package especially with respect to redistribution wiring interconnect layers 924 and redistribution via layers 920. Excess strain on the redistribution wiring interconnect layer 924 and redistribution via layers 920 may cause physical breaks in electrical connections to the semiconductor dies (700, 800), causing irreversible damage that may limit the function of the semiconductor package or render the semiconductor package inoperable. By forming the DBR within the redistribution structure 918 between the first redistribution structure portion 931 and the second redistribution structure portion 932, the reliability window may be improved such that deformation of the signal redistribution layout (i.e., redistribution via layers 920 and redistribution wiring interconnect layers 924 of the first redistribution structure portion 931 and the second redistribution structure portion 932) may be suppressed and strain may be reduced. In other words, the vias and the wiring interconnects within DBR may function as an electrically-isolated stiffener that reduces the deformation of signal-carrying wiring interconnects of the redistribution structure 918 caused by CTE mismatches between layers and materials that may result in material expansion and contraction.

Various embodiments allow for varying sizes, shapes, and designs of the DBR and the structures (e.g., redistribution via layers 920 and redistribution wiring interconnect layers 924) within the DBR. For example, referring to FIG. 1B, the DBR includes seven redistribution via layers 920 (i.e., the topmost redistribution via layer 920-7 is not populated with vias) and six redistribution wiring interconnect layers 924.

In some embodiments, fewer or more layers may be implemented within the redistribution structure 918 and therefore within the DBR. In some embodiments, the redistribution via layers 920 and redistribution wiring interconnect layers 924 may form separate columns of vias and wiring interconnects. For example, as illustrated in FIG. 1B, vias and wiring interconnects within the DBR are formed as five separate columns. The vias of the redistribution via layers 920 may be vertically staggered within each column with respect to a cross-sectional view, such that each next alternating via is not directly above or below the preceding or following via. The DBR is not limited to five columns, and may have fewer or more columns than what is illustrated in the example embodiment of FIG. 1B. The DBR may be formed based on design factors including but not limited to the density of the surrounding redistribution structure 918, the thickness of the redistribution structure 918, and the proximity of semiconductor dies within the semiconductor package between which the DBR is positioned. Other embodiments having various via and wiring interconnect structures within the DBR are contemplated within the scope of the present disclosure.

FIG. 1C is a top-down view of the expanded view of the DBR along the horizontal plane A-A′ of FIG. 1B. Referring to FIG. 1C, the top-down, or plan, view of the DBR illustrates the intersection of the vias and the wiring interconnects of the first redistribution via layer 920-1 and the first redistribution wiring interconnect layer 924-1. For ease of illustration, the vias of the first redistribution via layer 920-1 are illustrated as having a different material than the wiring interconnects of the first redistribution wiring interconnect layer 924-1, although the vias may be formed using the same materials as the wiring interconnects in actuality. In some embodiments, as illustrated in FIG. 1C, vias within the DBR may be aligned in rows and columns with respect to a plan view. In some embodiments, vias within the DBR may be offset, or staggered, with respect to adjacent vias in a plan view. In some embodiments, the density of the total area of the all of the vias within a given redistribution via layer 920 compared to the total area within that horizontal plane/layer (i.e., all area inside the DBR including the redistribution via layer 920 and surrounding dielectric material) in a plan view may be greater than 3% (e.g., total area of vias/DBR area, in which DBR area=total area of vias+total area of dielectric material). The array size of the vias within the DBR along the second horizontal distance hd2 may be less than, equal to, or greater than the array size of the vias of the first redistribution structure portion 931 and the second redistribution structure portion 932. For example, referring to FIG. 1D, the first redistribution structure portion 931 and the second redistribution structure portion 932 have an array size of seven vias along the second horizontal distance hd2, and the DBR has an equal number of vias along the second horizontal distance hd2. For ease of illustration, the redistribution via layers 920 and redistribution wiring interconnect layers 924 of the DBR are shown with dashed lines to indicate that they are underneath the topmost redistribution via layer 920-7.

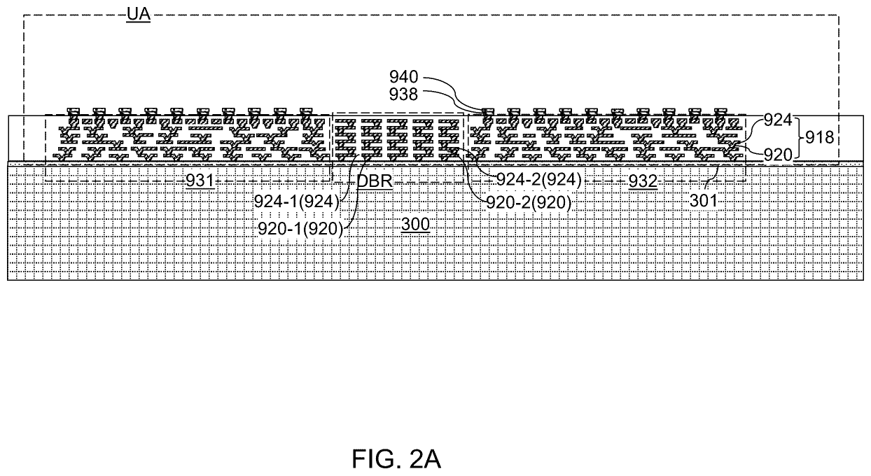

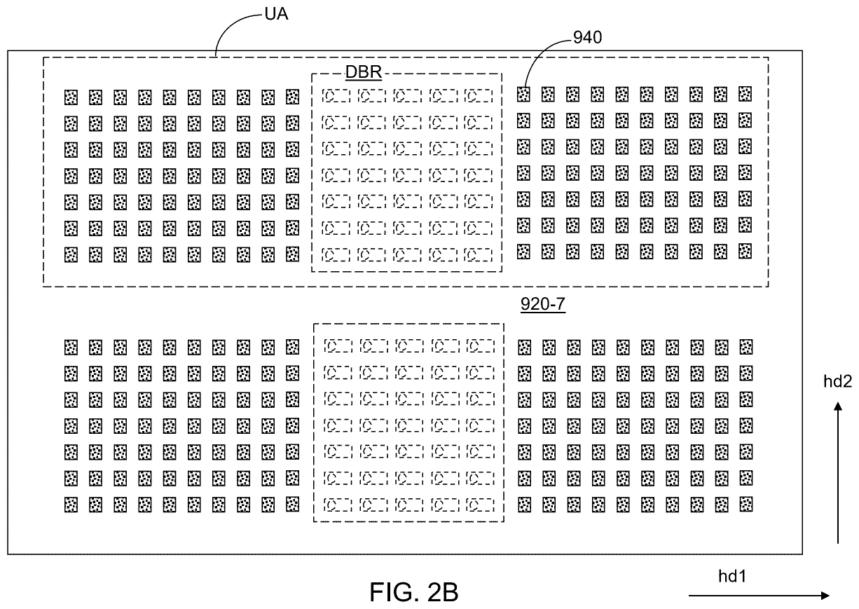

Referring to FIGS. 2A and 2B, at least one metallic material and a first material may be sequentially deposited over the front-side surface of the redistribution structures 918. The at least one metallic material comprises a material that may be used for metallic pads, such as copper. The thickness of the at least one metallic material may be in a range from 5 microns to 60 microns, such as from 10 microns to 30 microns, although lesser and greater thicknesses may also be used. The first material may comprise a first material suitable for C2 bonding, i.e., for microbump bonding. The thickness of the first material may be in a range from 2 microns to 30 microns, such as from 4 microns to 15 microns, although lesser and greater thicknesses may also be used.

The first material and the at least one metallic material may be patterned into discrete arrays of first solder material portions 940 and arrays of metal pad structures, which are herein referred to as arrays of redistribution-side metal pad structures 938. Each array of redistribution-side metal pad structures 938 is formed within a respective unit area UA. Each array of first solder material portions 940 is formed within a respective unit area UA. Each first solder material portion 940 may have a same horizontal cross-sectional shape as an underlying redistribution-side metal pad structure 938.

In one embodiment, the redistribution-side metal pad structures 938 may include, and/or may consist essentially of, copper or a copper-containing alloy. Other suitable materials are within the contemplated scope of disclosure. The thickness of the redistribution-side metal pad structures 938 may be in a range from 5 microns to 60 microns, although lesser or greater thicknesses may also be used. The redistribution-side metal pad structures 938 may have horizontal cross-sectional shapes of rectangles, rounded rectangles, circles, regular polygons, irregular polygons, or any other two-dimensional curvilinear shape having a closed periphery. In one embodiment, redistribution-side metal pad structures 938 may be configured for microbump bonding (i.e., C2 bonding), and may have a thickness in a range from 10 microns to 30 microns, although lesser or greater thicknesses may also be used. In this embodiment, each array of redistribution-side metal pad structures 938, such as copper pillars or under bump metallurgies (UBM), may be portions of an array of microbumps having a lateral dimension in a range from 10 microns to 25 microns, and having a pitch in a range from 20 microns to 50 microns.

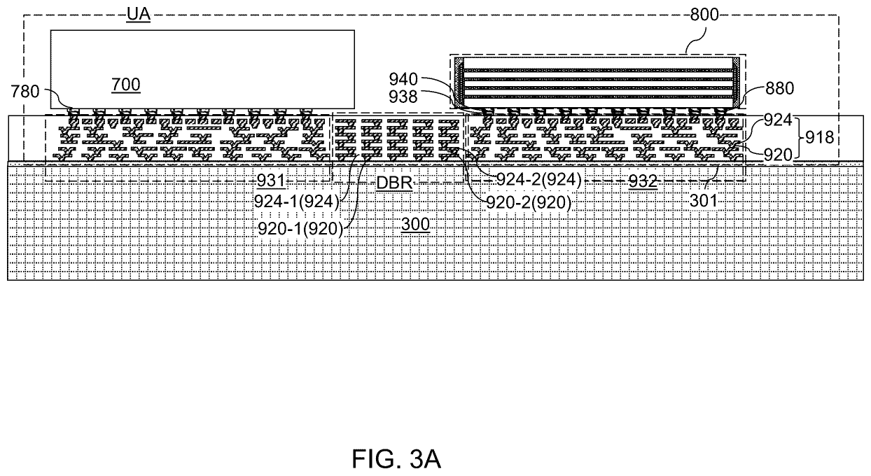

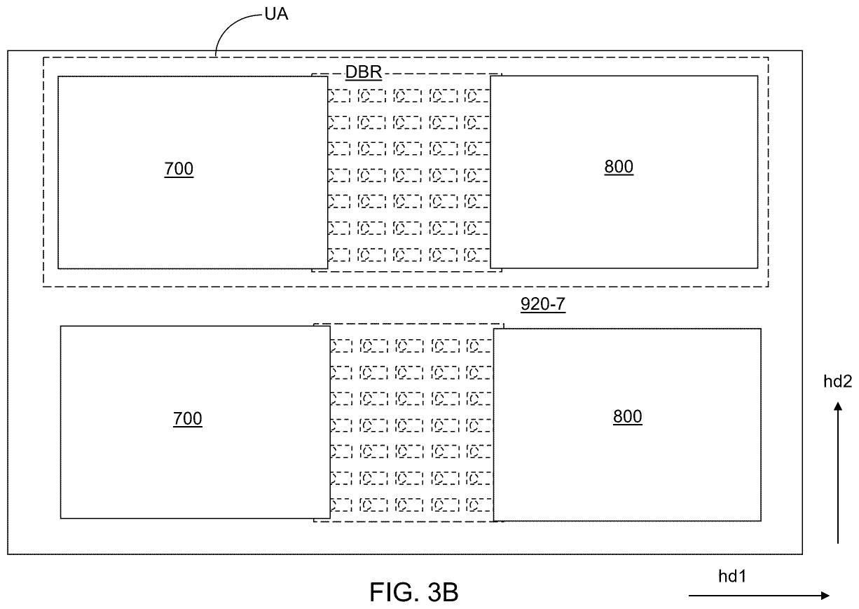

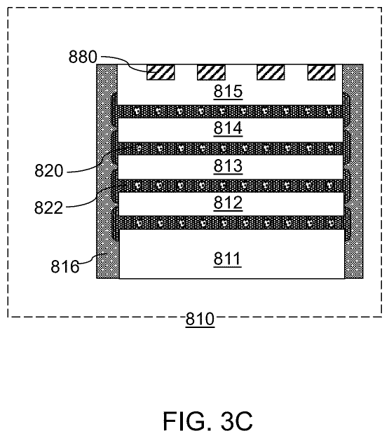

Referring to FIGS. 3A and 3B, a set of at least one semiconductor die (700, 800) may be bonded to the redistribution structure 918. In one embodiment, the redistribution structure 918 may be arranged as a two-dimensional periodic array, and multiple sets of at least one semiconductor die (700, 800) may be bonded to the redistribution structure 918 as a two-dimensional periodic rectangular array of sets of the at least one semiconductor die (700, 800). Each set of at least one semiconductor die (700, 800) includes at least one semiconductor die. Each set of at least one semiconductor die (700, 800) may include any set of at least one semiconductor die known in the art. In one embodiment, each set of at least one semiconductor die (700, 800) may comprise a plurality of semiconductor dies (700, 800). For example, each set of at least one semiconductor die (700, 800) may include at least one system-on-chip (SoC) die 700 and/or at least one memory die 800. Each SoC die 700 may comprise an application processor die, a central processing unit die, or a graphic processing unit die. In one embodiment, the at least one memory die 800 may comprise a high bandwidth memory (HBM) die that includes a vertical stack of static random-access memory dies. In one embodiment, the at least one semiconductor die (700, 800) may include at least one system-on-chip (SoC) die and a high bandwidth memory (HBM) die including a vertical stack of static random-access memory (SRAM) dies that are interconnected to one another through microbumps and are laterally surrounded by an epoxy molding material enclosure frame.

Referring to FIGS. 3A and 3C, each semiconductor die (700, 800) may comprise a respective array of die-side metal pad structures (780, 880). For example, each SoC die 700 may comprise an array of SoC metal pad structures 780, and each memory die 800 may comprise an array of memory-die metal pad structures 880. Each of the semiconductor dies (700, 800) may be positioned in a face-down position such that die-side metal pad structures (780, 880) face the first solder material portions 940. Each set of at least one semiconductor die (700, 800) may be placed within a respective unit area UA. Placement of the semiconductor dies (700, 800) may be performed using a pick and place apparatus so that each of the die-side metal pad structures (780, 880) is placed on a top surface of a respective one of the first solder material portions 940.

Generally, a redistribution structure 918 including redistribution-side metal pad structures 938 thereupon may be provided, and at least one semiconductor die (700, 800) including a respective set of die-side metal pad structures (780, 880) may be provided. The at least one semiconductor die (700, 800) may be bonded to the redistribution structure 918 using first solder material portions 940 that are bonded to a respective redistribution-side metal pad structure 938 and to a respective one of the die-side metal pad structures (780, 880). Generally, a first array of metallic joint structures can be formed. Each metallic joint structure may comprise a first metal pad structure (such as a redistribution-side metal pad structure 938), a second metal pad structure (such as a die-side metal pad structure (780, 880)), and a bump material portion (such as a first solder material portion 940).

In some embodiments, portions of the semiconductor dies (700, 800) may overlap or be positioned vertically over a portion of the DBR in a cross-sectional view. Sidewalls of the semiconductor dies (700, 800) may extend beyond the first redistribution structure portion 931 and the second redistribution structure portion 932 respectively and may be positioned vertically above portions of the DBR (i.e., in a same vertical plane). Portions of the DBR may be positioned beneath the semiconductor dies (700, 800), such that some of the redistribution layers 920 and redistribution wiring interconnect layers 924 (e.g., first redistribution via layer 920-1, first redistribution wiring interconnect layer 924-1, second redistribution via layer 920-2, second redistribution wiring interconnect layer 924-2, etc.) within the DBR may be positioned vertically below extending portions of the semiconductor dies (700, 800). In some embodiments, the DBR may be formed to be located between proximate sidewalls of the semiconductor dies (700, 800) with respect to a cross-sectional view. For example, outermost portions of the redistribution layers 920 and redistribution wiring interconnect layers 924 (e.g., first redistribution via layer 920-1, first redistribution wiring interconnect layer 924-1, second redistribution via layer 920-2, second redistribution wiring interconnect layer 924-2, etc.) within the DBR may be positioned vertically between the semiconductor dies (700, 800), such that sidewalls of the semiconductor dies (700, 800) do not extend outward to be positioned vertically above the DBR with respect to a cross-sectional view.

Referring to FIG. 3C, a high bandwidth memory (HBM) die 810 is illustrated, which may be used as a memory die 800 within the exemplary structures of FIGS. 3A and 3B. The HBM die 810 includes a vertical stack of static random-access memory dies (811, 812, 813, 814, 815) that are interconnected to one another through microbumps 820 and are laterally surrounded by an epoxy molding material enclosure frame 816. The gaps between vertically neighboring pairs of the random-access memory dies (811, 812, 813, 814, 815) may be filled with an HBM underfill material portions 822 that laterally surrounds a respective set of microbumps 820. The HBM die 810 may comprise an array of memory-die metal pad structures 880 configured to be bonded to a subset of an array of redistribution-side metal pad structures 938 within a unit area UA. The HBM die 810 may be configured to provide a high bandwidth as defined under JEDEC standards, i.e., standards defined by The JEDEC Solid State Technology Association.

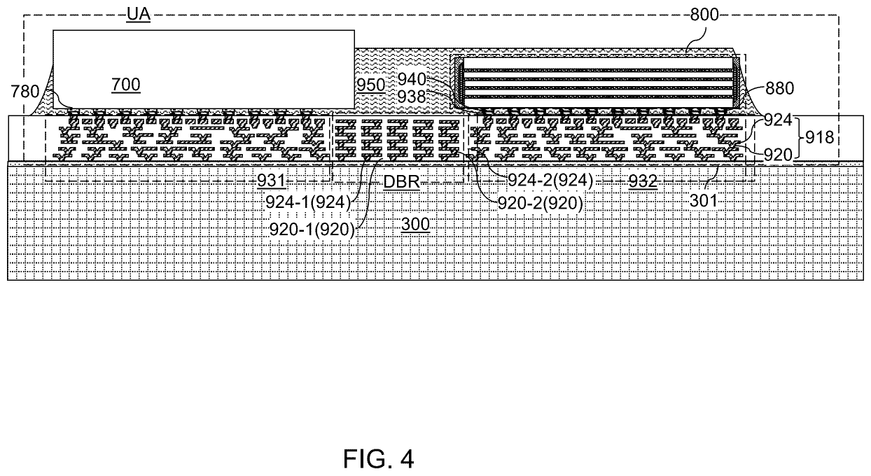

Referring to FIG. 4, a first underfill material may be applied into each gap between the redistribution structures 918 and sets of at least one semiconductor die (700, 800) that are bonded to the redistribution structures 918. The first underfill material may comprise any underfill material known in the art. A first underfill material portion 950 may be formed within each unit area UA between a redistribution structure 918 and an overlying set of at least one semiconductor die (700, 800). The first underfill material portions 950 may be formed by injecting the first underfill material around a respective array of first solder material portions 940 in a respective unit area UA. Any known underfill material application method may be used, which may be, for example, the capillary underfill method, the molded underfill method, or the printed underfill method.

Within each unit area UA, a first underfill material portion 950 may laterally surround, and contact, each of the first solder material portions 940 within the unit area UA. The first underfill material portion 950 may be formed around, and contact, the first solder material portions 940, the redistribution-side metal pad structures 938, and the die-side metal pad structures (780, 880) in the unit area UA.

Each redistribution structure 918 in a unit area UA comprises redistribution-side metal pad structures 938. At least one semiconductor die (700, 800) comprising a respective set of die-side metal pad structures (780, 880) is attached to the redistribution-side metal pad structures 938 through a respective set of first solder material portions 940 within each unit area UA. Within each unit area UA, a first underfill material portion 950 laterally surrounds the redistribution-side metal pad structures 938 and the die-side metal pad structures (780, 880) of the at least one semiconductor die (700, 800).

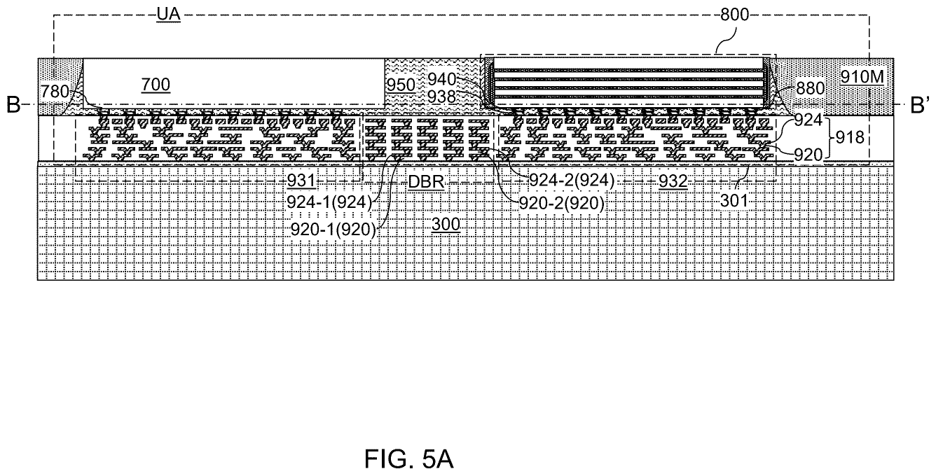

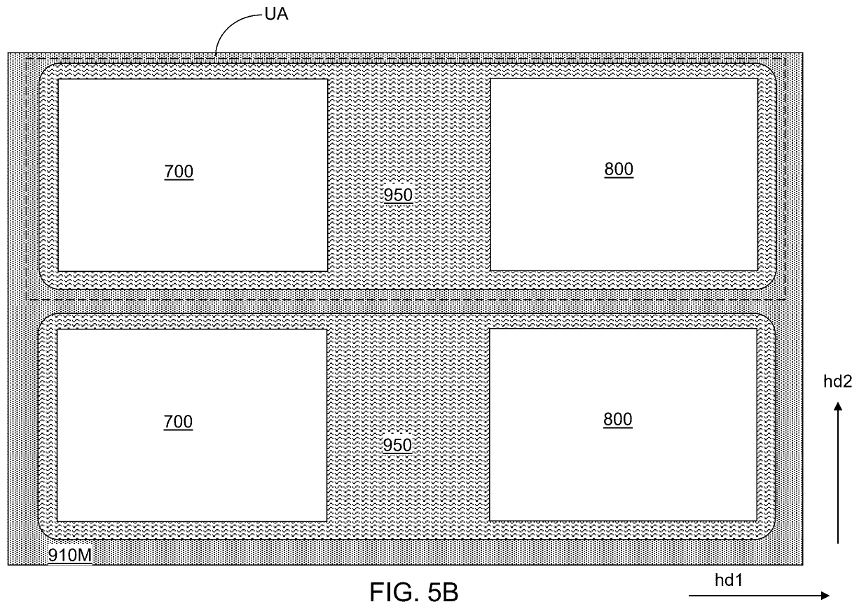

Referring to FIGS. 5A and 5B, an epoxy molding compound (EMC) may be applied to the gaps between contiguous assemblies of a respective set of semiconductor dies (700, 800) and a first underfill material portion 950. FIG. 5B is a top-down view of the expanded view of the exemplary structure along the horizontal plane B-B′ of FIG. 5A.

The EMC may include an epoxy-containing compound that may be hardened (i.e., cured) to provide a dielectric material portion having sufficient stiffness and mechanical strength. The EMC may include epoxy resin, hardener, silica (as a filler material), and other additives. The EMC may be provided in a liquid form or in a solid form depending on the viscosity and flowability. Liquid EMC provides better handling, good flowability, less voids, better fill, and less flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks, and may enhance flowability. The curing temperature of the EMC may be lower than the release (debonding) temperature of the first adhesive layer 301 if the adhesive layer includes a thermally debonding material. For example, the curing temperature of the EMC may be in a range from 125° C. to 150° C.

The EMC may be cured at a curing temperature to form an EMC matrix 910M that laterally surrounds and embeds each assembly of a set of semiconductor dies (700, 800) and a first underfill material portion 950. The EMC matrix 910M includes a plurality of epoxy molding compound (EMC) die frames that may be laterally adjoined to one another. Each EMC die frame is a portion of the EMC matrix 910M that is located within a respective unit area UA. Thus, each EMC die frame laterally surrounds and embeds a respective a set of semiconductor dies (700, 800) and a respective first underfill material portion 950. Young's modulus of pure epoxy is about 3.35 GPa, and Young's modulus of the EMC may be higher than Young's modulus of pure epoxy by adding additives. Young's modules of EMC may be greater than 3.5 GPa.

Portions of the EMC matrix 910M that overlies the horizontal plane including the top surfaces of the semiconductor dies (700, 800) may be removed by a planarization process. For example, the portions of the EMC matrix 910M that overlies the horizontal plane may be removed using a chemical mechanical planarization. The combination of the remaining portion of the EMC matrix 910M, the semiconductor dies (700, 800), the first underfill material portions 950, and the two-dimensional array of redistribution structures 918 comprises a reconstituted wafer 900W. Each portion of the EMC matrix 910M located within a unit area UA constitutes an EMC die frame.

Referring to FIG. 6, a second adhesive layer 401 may be applied to the physically exposed planar surface of the reconstituted wafer 900W, i.e., the physically exposed surfaces of the EMC matrix 910M, the semiconductor dies (700, 800), and the first underfill material portions 950. In one embodiment, the second adhesive layer 401 may comprise a same material as, or may comprise a different material from, the material of the first adhesive layer 301. If the first adhesive layer 301 comprises a thermally decomposing adhesive material, the second adhesive layer 401 comprises another thermally decomposing adhesive material that decomposes at a higher temperature, or may comprise a light-to-heat conversion material.

A second carrier substrate 400 may be attached to the second adhesive layer 401. The second carrier substrate 400 may be attached to the opposite side of the reconstituted wafer 900W relative to the first carrier substrate 300. Generally, the second carrier substrate 400 may comprise any material that may be used for the first carrier substrate 300. The thickness of the second carrier substrate 400 may be in a range from 500 microns to 2,000 microns, although lesser and greater thicknesses may also be used.

The first adhesive layer 301 may be decomposed by ultraviolet radiation or by a thermal anneal at a debonding temperature. In embodiments in which the first carrier substrate 300 includes an optically transparent material and the first adhesive layer 301 includes an LTHC layer, the first adhesive layer 301 may be decomposed by irradiating ultraviolet light through the transparent carrier substrate. The LTHC layer may be absorb the ultraviolet radiation and generate heat, which decomposes the material of the LTHC layer and cause the transparent first carrier substrate 300 to be detached from the reconstituted wafer 900W. In embodiments in which the first adhesive layer 301 includes a thermally decomposing adhesive material, a thermal anneal process at a debonding temperature may be performed to detach the first carrier substrate 300 from the reconstituted wafer 900W.

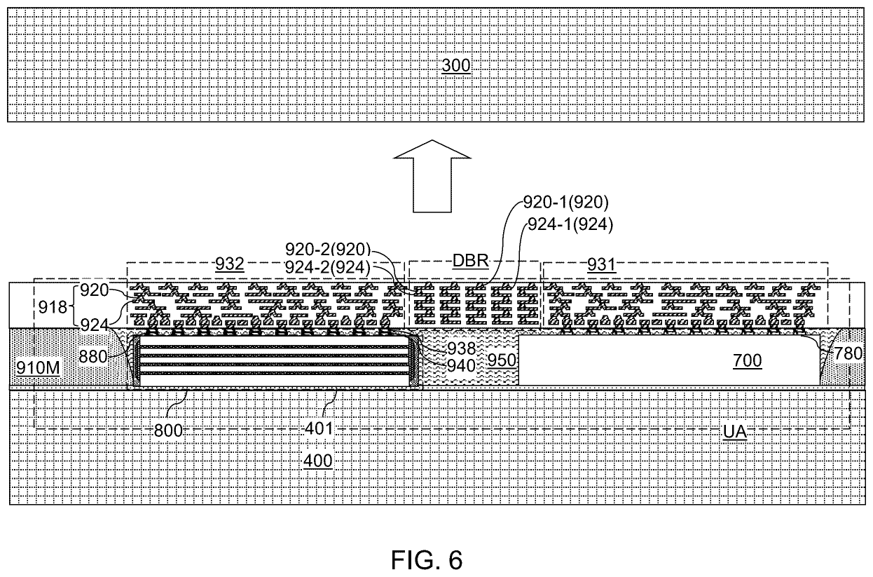

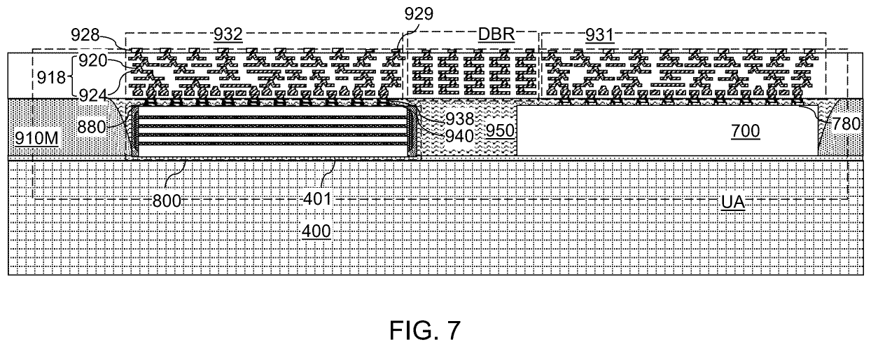

Referring to FIG. 7, fan-out bonding pads 928 and silicon bridge bonding pads 929 may be formed by depositing and patterning at least one metallic material that may function as bonding pads. The silicon bridge bonding pads 929 may be formed on portions of the first redistribution structure portion 931 and the second redistribution structure portion 932 that are to be connected via a silicon bridge. For example, as illustrated in FIG. 7, the proximal two via connections within both the first redistribution structure portion 931 and the second redistribution structure portion 932 have silicon bridge bonding pads 929 formed thereon. The silicon bridge bonding pads 929 may be formed on connections to the DBR enhanced vias, specifically the vias of the first redistribution via layer 920-1 within the DBR. The metallic fill material for the fan-out bonding pads 928 and silicon bridge bonding pads 929 may include copper. Other suitable materials are within the contemplated scope of disclosure. The thickness of the fan-out bonding pads 928 and silicon bridge bonding pads 929 may be in a range from 5 microns to 100 microns, although lesser or greater thicknesses may also be used. The fan-out bonding pads 928 and silicon bridge bonding pads 929 may have horizontal cross-sectional shapes of rectangles, rounded rectangles, or circles. Other suitable shapes are within the contemplated scope of disclosure. In embodiments in which the fan-out bonding pads 928 and silicon bridge bonding pads 929 are formed as C4 (controlled collapse chip connection) pads, the thickness of the fan-out bonding pads 928 may be in a range from 5 microns to 50 microns, although lesser or greater thicknesses may also be used. Alternatively, the fan-out bonding pads 928 and silicon bridge bonding pads 929 may be configured for microbump bonding (i.e., C2 bonding), and may have a thickness in a range from 30 microns to 100 microns, although lesser or greater thicknesses may also be used. In such an embodiment, the fan-out bonding pads 928 and silicon bridge bonding pads 929 may be formed as an array of micropads (such as copper pillars or UBMs) having a lateral dimension in a range from 10 microns to 25 microns, and having a pitch in a range from 20 microns to 50 microns. In some embodiments, the fan-out bonding pads 928 may be formed as C4 pads, and the silicon bridge bonding pads 929 may be formed as C2 pads.

The fan-out bonding pads 928 and the silicon bridge bonding pads 929 may be formed on the opposite side of the EMC matrix 910M and the two-dimensional array of sets of semiconductor dies (700, 800) relative to the redistribution structure layer. The redistribution structure layer includes a two-dimensional array of redistribution structures 918. Each redistribution structure 918 may be located within a respective unit area UA. Each redistribution structure 918 may comprise redistribution via layers 920 and redistribution wiring interconnect layers 924, fan-out bonding pads 928, and silicon bridge bonding pads 929. The fan-out bonding pads 928 and silicon bridge bonding pads 929 may be located on an opposite side of the redistribution-side metal pad structures 938 relative to the redistribution structure 918. The fan-out bonding pads 928 and silicon bridge bonding pads 929 within the first redistribution structure portion 931 and the second redistribution structure portion 932 are electrically connected to a respective one of the redistribution-side metal pad structures 938. The silicon bridge bonding pads 929 within the DBR are not electrically connected to any structures outside of the DBR and the silicon bridge to be formed in subsequent processes.

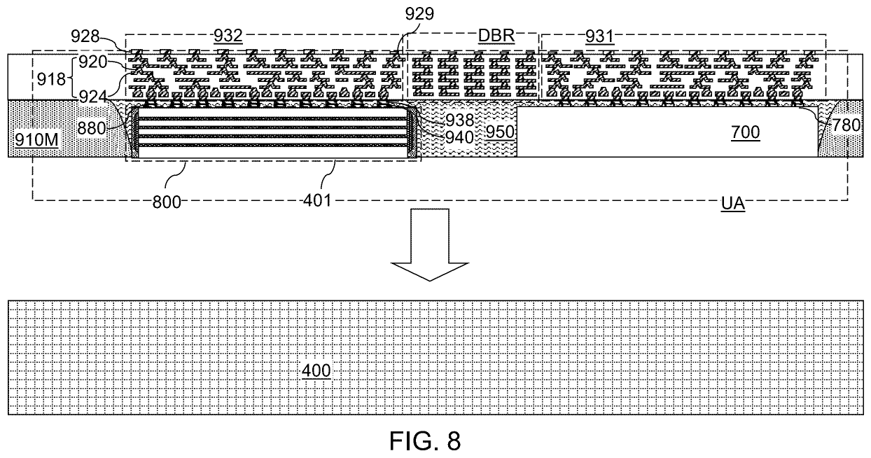

Referring to FIG. 8, the second adhesive layer 401 may be decomposed by ultraviolet radiation or by a thermal anneal at a debonding temperature. In embodiments in which the second carrier substrate 400 includes an optically transparent material and the second adhesive layer 401 includes an LTHC layer, the second adhesive layer 401 may be decomposed by irradiating ultraviolet light through the transparent carrier substrate. In embodiments in which the second adhesive layer 401 includes a thermally decomposing adhesive material, a thermal anneal process at a debonding temperature may be performed to detach the second carrier substrate 400 from the reconstituted wafer 900W.

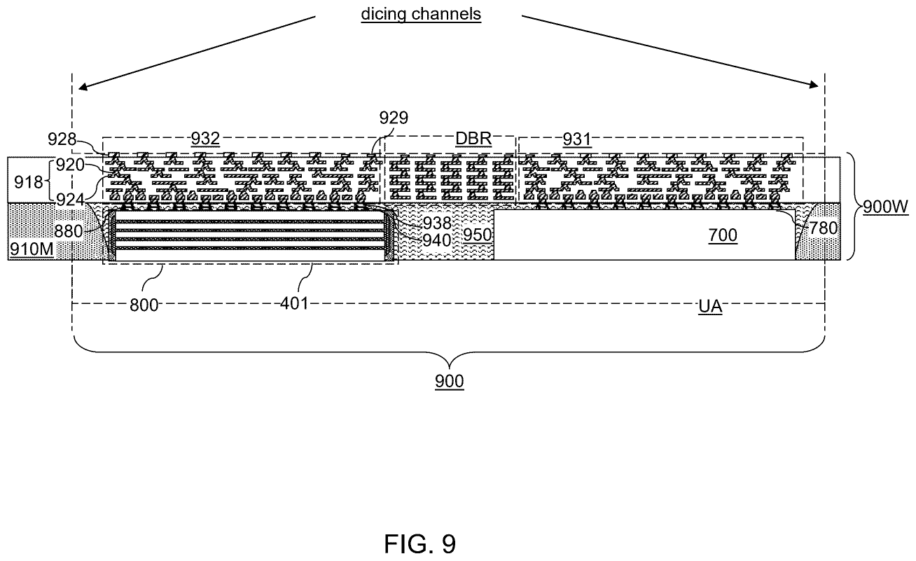

Referring to FIG. 9, the reconstituted wafer 900W including the fan-out bonding pads 928 may be subsequently diced along dicing channels by performing a dicing process. The dicing channels correspond to the boundaries between neighboring pairs of die areas DA. Each diced unit from the reconstituted wafer 900W comprises a fan-out package 900. In other words, each diced portion of the assembly of the two-dimensional array of sets of semiconductor dies (700, 800), the two-dimensional array of first underfill material portions 950, the EMC matrix 910M, and the two-dimensional array of redistribution structures 918 constitutes a fan-out package 900. Each diced portion of the EMC matrix 910M constitutes a molding compound die frame 910. Each diced portion of the redistribution structure layer (which includes the two-dimensional array of redistribution structures 918) constitutes a redistribution structure 918.

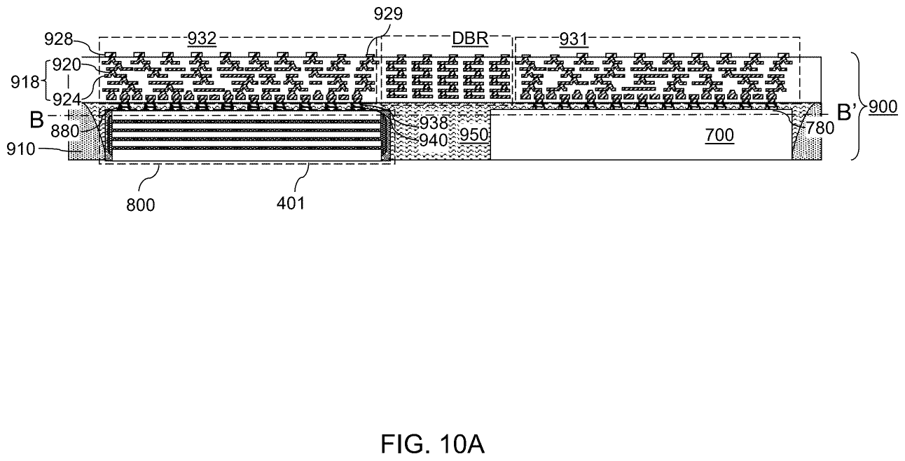

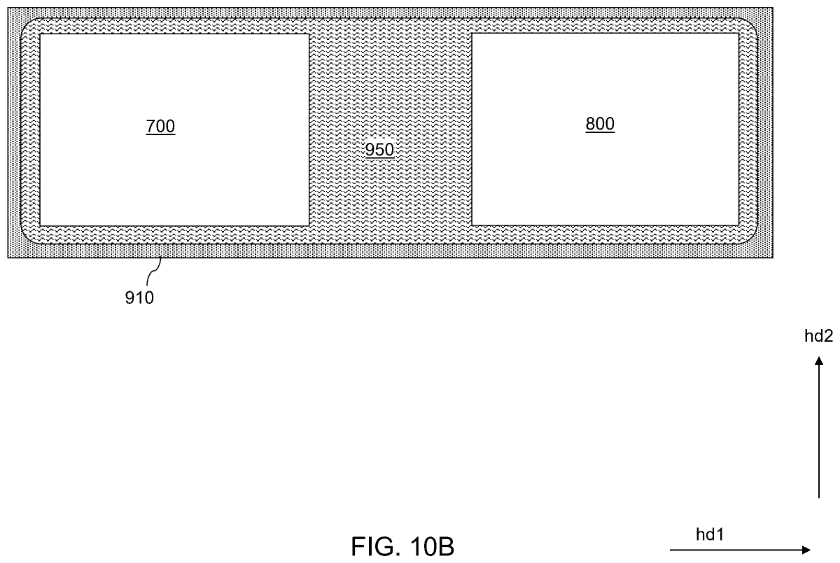

Referring to FIGS. 10A and 10B, a fan-out package 900 obtained by dicing the exemplary structure at the processing steps of FIG. 10 is illustrated. FIG. 10B is a top-down view of the expanded view of the exemplary structure along the horizontal plane B-B′ of FIG. 10A. The fan-out package 900 comprises a redistribution structure 918 including redistribution-side metal pad structures 938, at least one semiconductor die (700, 800) comprising a respective set of die-side metal pad structures (780, 880) that is attached to the redistribution-side metal pad structures 938 through a respective set of first solder material portions 940, a first underfill material portion 950 laterally surrounding the redistribution-side metal pad structures 938 and the die-side metal pad structures (780, 880) of the at least one semiconductor die (700, 800).

The fan-out package 900 may comprise a molding compound die frame 910 laterally surrounding the at least one semiconductor die (700, 800) and comprising a molding compound material. In one embodiment, the molding compound die frame 910 comprises sidewalls that are vertically coincident with sidewalls of the redistribution structure 918, i.e., located within same vertical planes as the sidewalls of the redistribution structure 918. Generally, the molding compound die frame 910 may be formed around the at least one semiconductor die (700, 800) after formation of the first underfill material portion 950 within each fan-out package 900. The molding compound material contacts a peripheral portion of a planar surface of the redistribution structure 918.

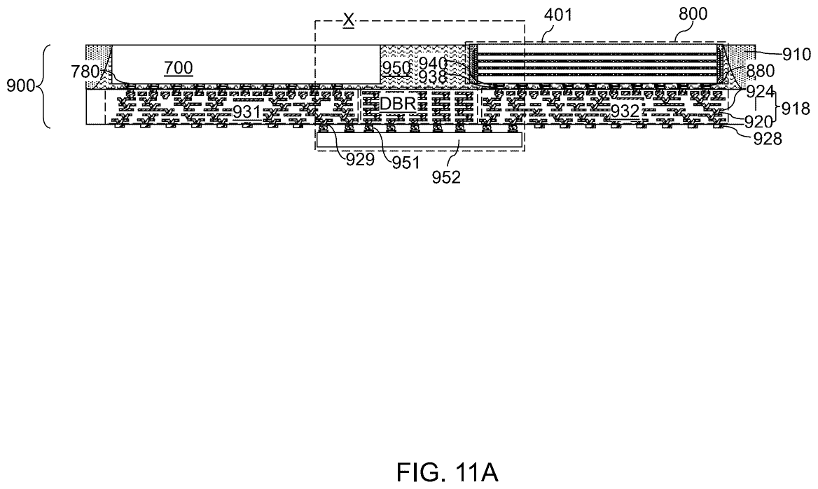

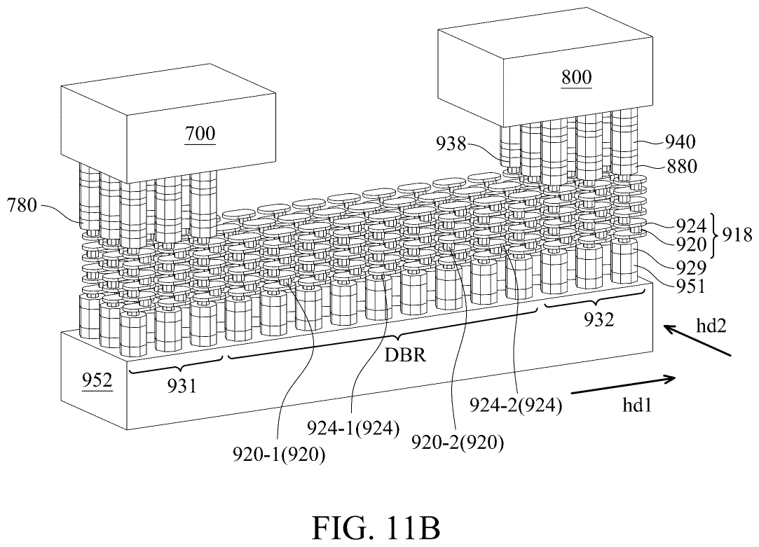

Referring to FIGS. 11A and 11B, bridge solder material portions 951 may be attached to silicon bridge bonding pads 929 within the first redistribution structure portion 931, the second redistribution structure portion 932, and DBR. A silicon bridge 952 may be formed upon the bridge solder material portions 951. The silicon bridge 952 may be used to electrically connect the silicon dies (700, 800) through the vias and wiring interconnects of the first redistribution structure portion 931 and the second redistribution structure portion 932. The silicon bridge 952 may include one or more layers of vias and wiring interconnects (not shown) to electrically connect the silicon dies (700, 800). In some embodiments, the redistribution via layers 920 and redistribution wiring interconnect layers 924 of the DBR may be electrically connected to portions of the silicon bridge 952 (e.g., for electrical dissipation purposes) through the first redistribution via layer 920-1. In some embodiments, the vias and wiring interconnects of the redistribution via layers 920 and redistribution wiring interconnect layers 924 within the DBR may be electrically connected to portions of the silicon bridge 952 through the first redistribution via layer 920-1, such that the silicon bridge 952 mirrors a portion or all of the DBR including the first redistribution via layer 920-1, first redistribution wiring interconnect layer 924-1, a second redistribution via layer 920-2, a second redistribution wiring interconnect layer 924-2, and so on. Such an embodiment may provide additional reduction to deformation caused by CTE mismatch throughout the semiconductor package. In some embodiments, the vias and wiring interconnects of the redistribution via layers 920 and redistribution wiring interconnect layers 924 within the DBR may be electrically isolated from portions of the silicon bridge 952, such that the first redistribution via layer 920-1 does not connect with any wiring interconnect materials within the silicon bridge 952. In some embodiments, a silicon bridge may not be used, and the DBR may be electrically isolated from all other signal-transferring structures. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 11B. For example, FIG. 11B illustrates the redistribution structure 918 as having one less redistribution via layer 920 and one less redistribution wiring interconnect layer 924 as compared to FIG. 11A. As another example, the width of the DBR region as illustrated in FIG. 11B appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 11B is illustrated as not including the first underfill material portion 950.

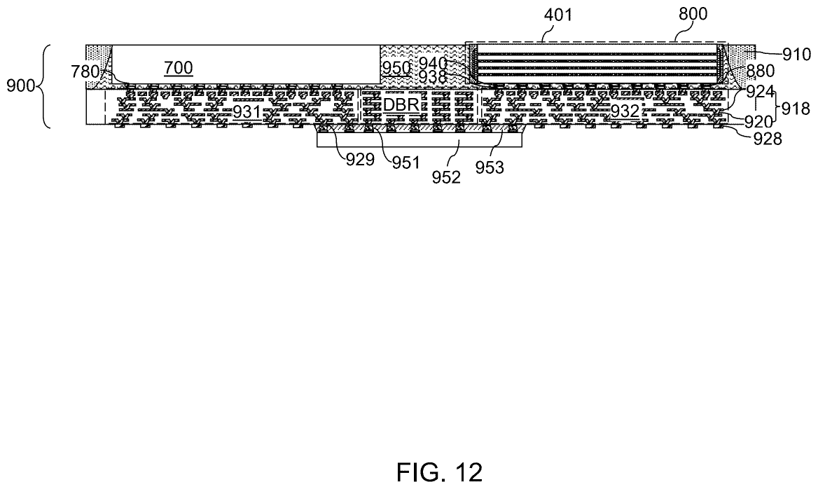

Referring to FIG. 12, a bridge underfill material portion 953 may be formed around the bridge solder material portions 951 by applying and shaping a bridge underfill material. The bridge underfill material portion 953 may be formed around the bridge solder material portions 951 by applying and shaping the bridge underfill material. The bridge underfill material portion 953 may be formed by injecting the bridge underfill material around the array of bridge solder material portions 951 after the bridge solder material portions 951 are reflowed. Any known underfill material application method may be used, which may be, for example, the capillary underfill method, the molded underfill method, or the printed underfill method.

The bridge underfill material portion 953 may contact each of the bridge solder material portions 951 (which may be C4 solder balls or C2 solder caps), and may contact vertical sidewalls of the silicon bridge 952. The bridge underfill material portion 953 is formed between the redistribution structure 918 and the silicon bridge 952. The bridge underfill material portion 953 laterally surrounds, and contacts, the array of bridge solder material portions 951 and the silicon bridge 952. According to an aspect of the present disclosure, the bridge underfill material portion 953 may be formed directly on each sidewall of the silicon bridge 952.

In one embodiment, the bridge underfill material portion 953 may include tapered sidewalls that extend continuously from a respective sidewall of the silicon bridge 952 to a planar surface (such as the top surface) of the redistribution structure 918. The taper angle of the tapered sidewalls may be in a range from 10 degrees to 80 degrees, such as from 30 degrees to 60 degrees, although lesser and greater taper angles may also be used. The taper angle may, or may not, be uniform. In one embodiment, the tapered sidewalls may have a same taper angle (as measured from a vertical direction) throughout.

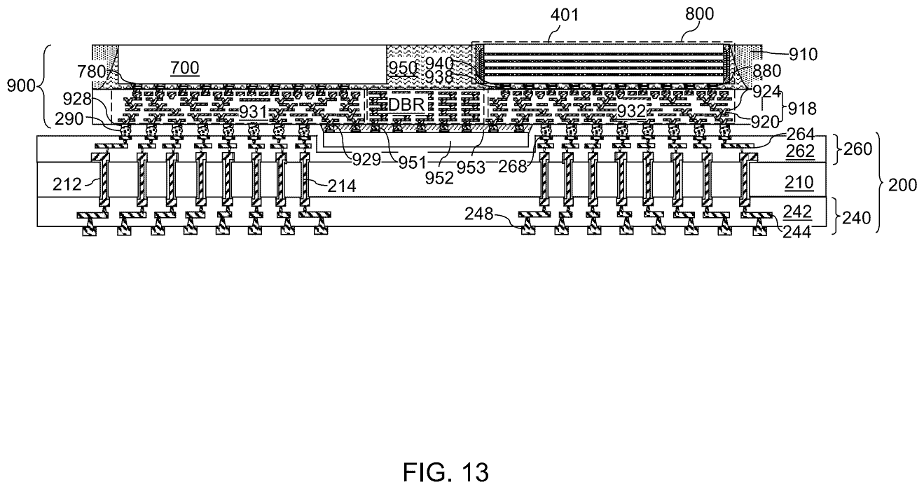

Referring to FIG. 13, second solder material portions 290 may be attached to the fan-out bonding pads 928. A package substrate 200 may be bonded to the fan-out package 900 through the second solder material portions 290. The package substrate 200 may be a cored package substrate including a core substrate 210, or a coreless package substrate that does not include a package core. Alternatively, the package substrate 200 may include a system-on-integrated package substrate (SoIS) including redistribution layers and/or dielectric interlayers, at least one embedded interposer (such as a silicon interposer). Such a system-integrated package substrate may include layer-to-layer interconnections using bonding material portions, underfill material portions (such as molded underfill material portions), and/or an optional adhesion film (not shown). While the present disclosure is described using an exemplary substrate package, it is understood that the scope of the present disclosure is not limited by any particular type of substrate package and may include an SoIS. The core substrate 210 may include a glass epoxy plate including an array of through-plate holes. An array of through-core via structures 214 including a metallic material may be provided in the through-plate holes. Each through-core via structure 214 may, or may not, include a cylindrical hollow therein. Optionally, dielectric liners 212 may be used to electrically isolate the through-core via structures 214 from the core substrate 210.

The package substrate 200 may include board-side surface laminar circuit (SLC) 240 and a chip-side surface laminar circuit (SLC) 260. The board-side SLC may include board-side insulating layers 242 embedding board-side wiring interconnects 244. The chip-side SLC 260 may include chip-side insulating layers 262 embedding chip-side wiring interconnects 264. The board-side insulating layers 242 and the chip-side insulating layers 262 may include a photosensitive epoxy material that may be lithographically patterned and subsequently cured. The board-side wiring interconnects 244 and the chip-side wiring interconnects 264 may include copper that may be deposited by electroplating within patterns in the board-side insulating layers 242 or the chip-side insulating layers 262.

In embodiments that include a silicon bridge (e.g., silicon bridge 952), the chip-side insulating layers 262 may be formed around the silicon bridge 952. In some embodiments, the chip-side insulating layers 262 may be formed around and encapsulate the silicon bridge 952. In some embodiments, the chip-side insulating layers 262 may be formed with an opening larger than the shape and dimensions of the silicon bridge 952 such that underfill material may be inserted between the chip-side insulating layers 262 and the silicon bridge 952.

In one embodiment, the package substrate 200 includes a chip-side surface laminar circuit 260 comprising chip-side wiring interconnects 264 connected to an array of chip-side bonding pads 268 that may be bonded to the array of second solder material portions 290, and a board-side surface laminar circuit 240 including board-side wiring interconnects 244 connected to an array of board-side bonding pads 248. The array of board-side bonding pads 248 may be configured to allow bonding through solder balls. The array of chip-side bonding pads 268 may be configured to allow bonding through C4 solder balls. Generally, any type of package substrate 200 may be used. While the present disclosure is described using an embodiment in which the package substrate 200 includes a chip-side surface laminar circuit 260 and a board-side surface laminar circuit 240, embodiments are expressly contemplated herein in which one of the chip-side surface laminar circuit 260 and the board-side surface laminar circuit 240 is omitted, or is replaced with an array of bonding structures such as microbumps. In an illustrative example, the chip-side surface laminar circuit 260 may be replaced with an array of microbumps or any other array of bonding structures.

The second solder material portions 290 attached to the fan-out bonding pads 928 of the fan-out package 900 may be disposed on the array of the chip-side bonding pads 268 of the package substrate 200. A reflow process may be performed to reflow the second solder material portions 290, thereby inducing bonding between the fan-out package 900 and the package substrate 200. In one embodiment, the second solder material portions 290 may include C4 solder balls, and the fan-out package 900 may be attached to the package substrate 200 using an array of C4 solder balls. Generally, a second array of metallic joint structures can be formed. Each metallic joint structure may comprise a first metal pad structure (such as a chip-side bonding pad 268), a second metal pad structure (such as a fan-out bonding pad 928), and a bump material portion (such as a second solder material portion 290).

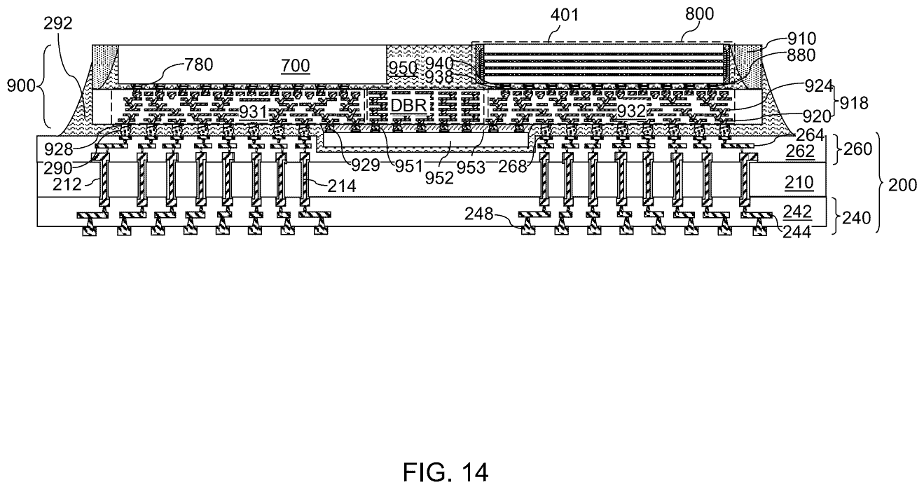

Referring to FIG. 14, a second underfill material portion 292 may be formed around the second solder material portions 290, the bridge underfill material portion 953, and the silicon bridge 952 by applying and shaping a second underfill material. The second underfill material portion 292 may be formed around the second solder material portions 290, the bridge underfill material portion 953, and the silicon bridge 952 by applying and shaping the second underfill material. The second underfill material portion 292 may be formed by injecting the second underfill material around the array of second solder material portions 290, the bridge underfill material portion 953, and the silicon bridge 952 after the second solder material portions 290 are reflowed. Any known underfill material application method may be used, which may be, for example, the capillary underfill method, the molded underfill method, or the printed underfill method.

The second underfill material portion 292 may be formed between the redistribution structure 918 and the package substrate 200, and between the silicon bridge 952 and the package substrate 200 in embodiments which include a silicon bridge. According to an aspect of the present disclosure, the second underfill material portion 292 may be formed directly on each sidewall of the molding compound die frame 910. The second underfill material portion 292 may contact each of the second solder material portions 290 (which may be C4 solder balls or C2 solder caps), and may contact vertical sidewalls of the fan-out package 900 and the silicon bridge 952. The second underfill material portion laterally surrounds, and contacts, the array of second solder material portions 290 and the fan-out package 900.

In one embodiment, the second underfill material portion 292 may include tapered sidewalls that extend continuously from a respective sidewall of the molding compound die frame 910 to a planar surface (such as the top surface) of the package substrate 200. The taper angle of the tapered sidewalls may be in a range from 10 degrees to 80 degrees, such as from 30 degrees to 60 degrees, although lesser and greater taper angles may also be used. The taper angle may, or may not, be uniform. In one embodiment, the tapered sidewalls may have a same taper angle (as measured from a vertical direction) throughout.

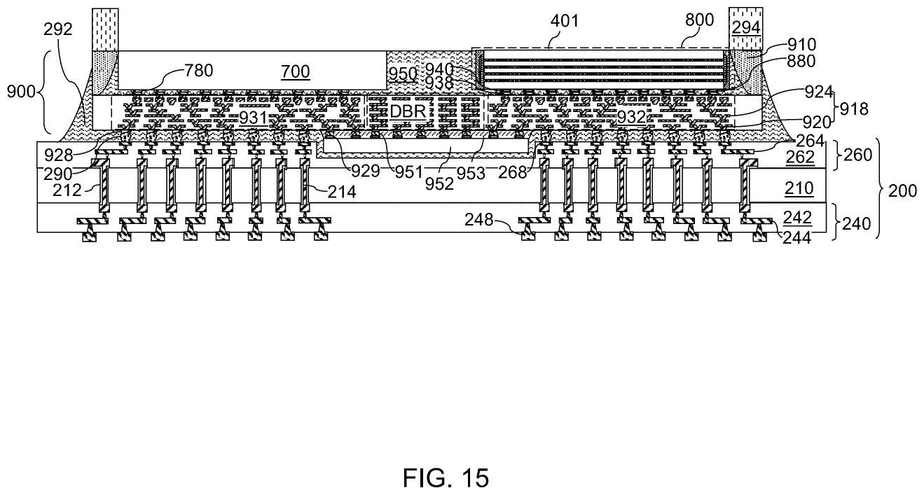

Referring to FIG. 15, a stabilization structure 294, such as a cap structure, stiffener, or a ring structure, may be attached to the assembly of the fan-out package 900 and the package substrate 200 to reduce deformation of the assembly during subsequent processing steps and/or during usage of the assembly.

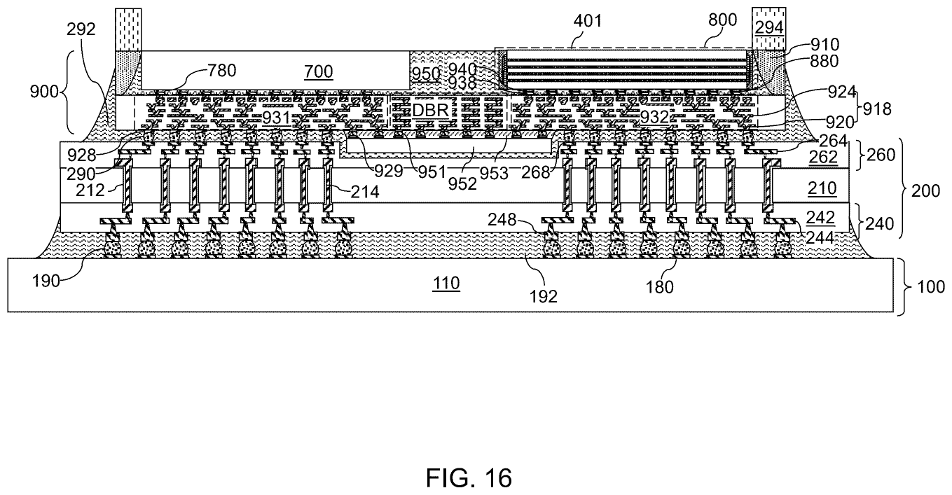

Referring to FIG. 16, a printed circuit board (PCB) 100 including a PCB substrate 110 and PCB bonding pads 180 may be provided. The PCB 100 includes a printed circuitry (not shown) at least on one side of the PCB substrate 110. An array of solder joints 190 may be formed to bond the array of board-side bonding pads 248 to the array of PCB bonding pads 180. The solder joints 190 may be formed by disposing an array of solder balls between the array of board-side bonding pads 248 and the array of PCB bonding pads 180, and by reflowing the array of solder balls. An underfill material portion 192 may be formed around the solder joints 190 by applying and shaping an underfill material. The package substrate 200 is attached to the PCB 100 through the array of solder joints 190.

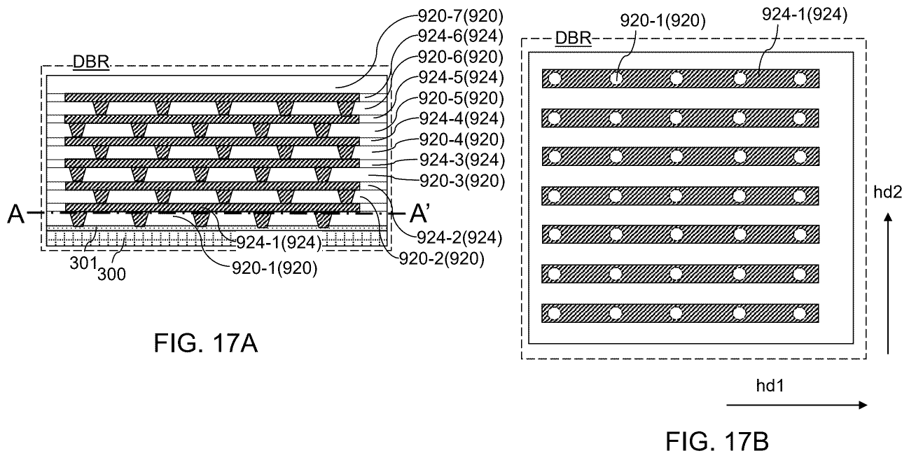

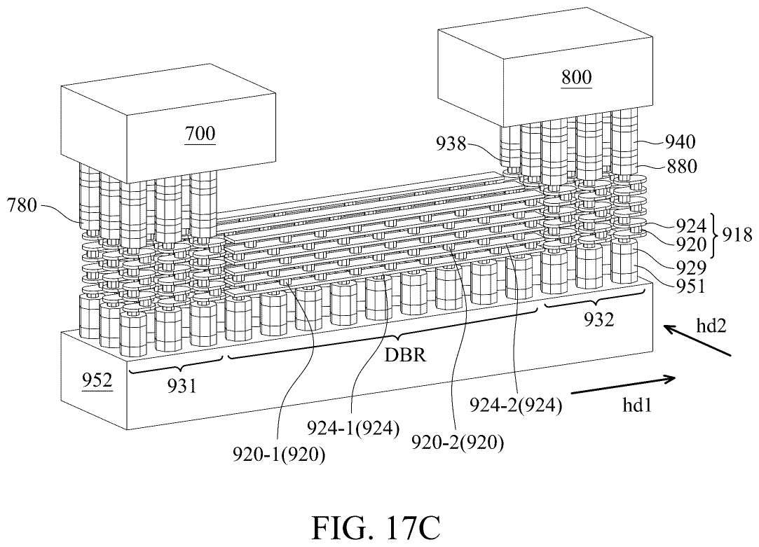

Referring to FIGS. 17A and 17B, an expanded view of a first alternative configuration of the DBR outlined in FIG. 1A is illustrated. The DBR as illustrated in FIGS. 17A and 17B may be formed alternatively to the DBR illustrated in FIGS. 1A-16. The vias of the first redistribution via layer 920-1, the second redistribution via layer 920-2, and any subsequent vias of the redistribution via layers 920 may be vertically staggered with respect to a cross-sectional view, such that each next alternating via is not directly above or below the preceding or following via of the adjacent redistribution via layers 920.

FIG. 17B is a top-down view of the expanded view of the DBR along the horizontal plane A-A′ of FIG. 17A. Referring to FIG. 17B, the top-down, or plan, view of the DBR illustrates the intersection of the vias and the wiring interconnects of the first redistribution via layer 920-1 and the first redistribution wiring interconnect layer 924-1. For ease of illustration, the vias of the first redistribution via layer 920-1 are illustrated as having a different material than the wiring interconnects of the first redistribution wiring interconnect layer 924-1, although they may be formed using the same materials in actuality.

Redistribution wiring interconnect layers 924 within the DBR may include wiring interconnects that that extend linearly in a first horizontal direction hd1 and laterally to connect vias of the redistribution via layers 920 within the DBR. For example, the wiring interconnects of the first redistribution wiring interconnect layer 924-1 and the second redistribution wiring interconnect layer 924-2 may extend linearly in a first horizontal direction hd1 and in parallel along a first horizontal direction hd1 to electrically connect vias of the first redistribution via layer 920-1 and the second redistribution via layer 920-2. The wiring interconnects of the first redistribution wiring interconnect layer 924-1 and the second redistribution wiring interconnect layer 924-2 may be formed in rows in a striped pattern with respect to a plan view. The wiring interconnects of the first redistribution wiring interconnect layer 924-1 and the second redistribution wiring interconnect layer 924-2 may extend linearly and laterally between and perpendicular to proximate perimeters of the first redistribution structure portion 931 and the second redistribution structure portion 932. After forming the DBR according to FIGS. 17A and 17B, the semiconductor package may be formed according to the processes described with reference to FIGS. 2A-16.

Referring to FIG. 17C, a three-dimensional expanded view of the first alternative configuration of the outlined region X of an intermediate structure after attaching a silicon bridge in FIG. 11A is illustrated. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 17C. For example, FIG. 17C illustrates the redistribution structure 918 as having one less redistribution via layer 920 and one less redistribution wiring interconnect layer 924 as compared to FIG. 11A. As another example, the width of the DBR region as illustrated in FIG. 17C appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 17C is illustrated as not including the first underfill material portion 950.

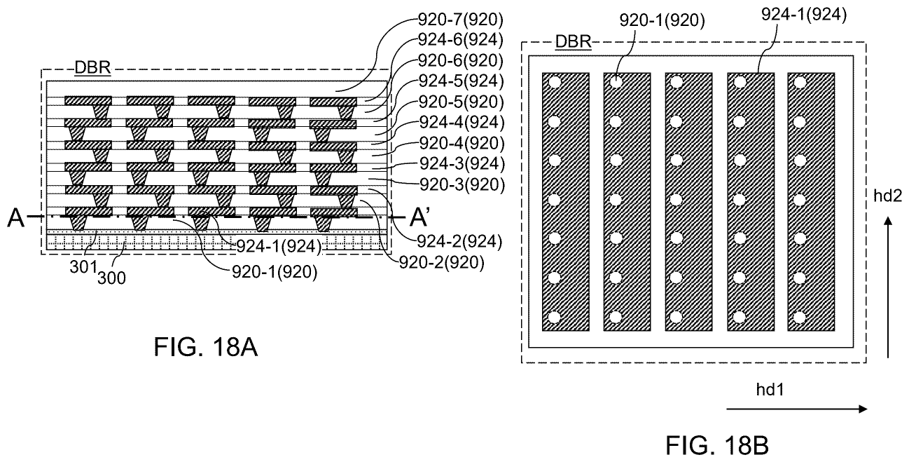

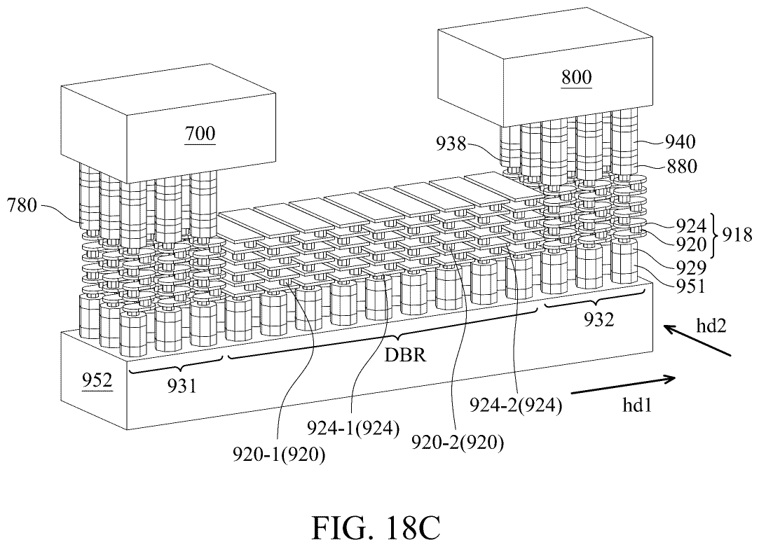

Referring to FIGS. 18A and 18B, an expanded view of a second alternative configuration of the DBR outlined in FIG. 1A is illustrated. The DBR as illustrated in FIGS. 18A and 18B may be formed alternatively to the DBR illustrated in FIGS. 1A-17B. The vias of the first redistribution via layer 920-1, the second redistribution via layer 920-2, and any subsequent vias of the redistribution via layers 920 may be vertically staggered with respect to a cross-sectional view, such that each next alternating via is not directly above or below the preceding or following via of the adjacent redistribution via layers 920.

FIG. 18B is a top-down view of the expanded view of the DBR along the horizontal plane A-A′ of FIG. 18A. Referring to FIG. 18B, the top-down, or plan, view of the DBR illustrates the intersection of the vias and the wiring interconnects of the first redistribution via layer 920-1 and the first redistribution wiring interconnect layer 924-1. For ease of illustration, the vias of the first redistribution via layer 920-1 are illustrated as having a different material than the wiring interconnects of the first redistribution wiring interconnect layer 924-1, although they may be formed using the same materials in actuality.

Redistribution wiring interconnect layers 924 within the DBR may include wiring interconnects that extend linearly and laterally to connect vias of the redistribution via layers 920 within the DBR. For example, the wiring interconnects of the first redistribution wiring interconnect layer 924-1 and the second redistribution wiring interconnect layer 924-2 may extend linearly, laterally, and in parallel along a second horizontal direction hd2 to electrically connect vias of the first redistribution via layer 920-1 and the second redistribution via layer 920-2. The wiring interconnects of the first redistribution wiring interconnect layer 924-1 and the second redistribution wiring interconnect layer 924-2 may be formed in rows in a striped pattern with respect to a plan view. The wiring interconnects of the first redistribution wiring interconnect layer 924-1 and the second redistribution wiring interconnect layer 924-2 may extend linearly and laterally along and parallel to proximate perimeters of the first redistribution structure portion 931 and the second redistribution structure portion 932. After forming the DBR according to FIGS. 18A and 18B, the semiconductor package may be formed according to the processes described with reference to FIGS. 2A-16.

Referring to FIG. 18C, a three-dimensional expanded view of the second alternative configuration of the outlined region X of an intermediate structure after attaching a silicon bridge in FIG. 11A is illustrated. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 18C. For example, FIG. 18C illustrates the redistribution structure 918 as having one less redistribution via layer 920 and one less redistribution wiring interconnect layer 924 as compared to FIG. 11A. As another example, the width of the DBR region as illustrated in FIG. 18C appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 18C is illustrated as not including the first underfill material portion 950.

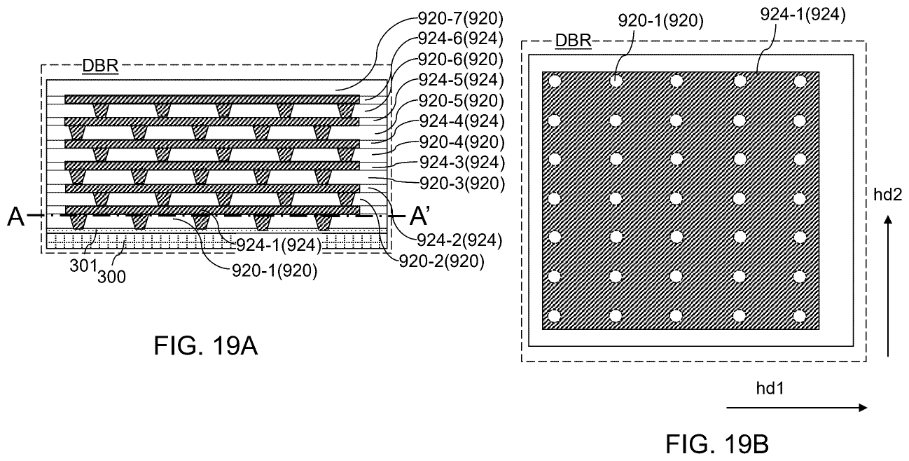

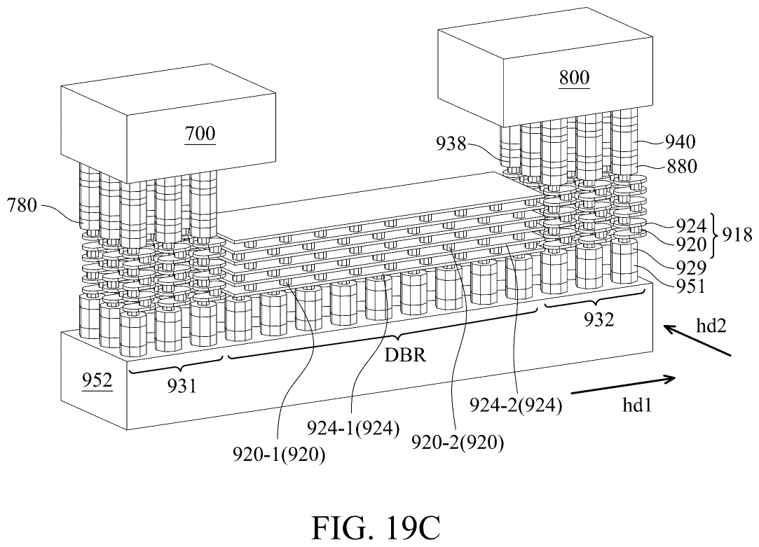

Referring to FIGS. 19A and 19B, an expanded view of a third alternative configuration of the DBR outlined in FIG. 1A is illustrated. The DBR as illustrated in FIGS. 19A and 19B may be formed alternatively to the DBR illustrated in FIGS. 1A-18B. The vias of the first redistribution via layer 920-1, the second redistribution via layer 920-2, and any subsequent vias of the redistribution via layers 920 may be vertically staggered with respect to a cross-sectional view, such that each next alternating via is not directly above or below the preceding or following via of the adjacent redistribution via layers 920.

FIG. 19B is a top-down view of the expanded view of the DBR along the horizontal plane A-A′ of FIG. 19A. Referring to FIG. 19B, the top-down, or plan, view of the DBR illustrates the intersection of the vias and the wiring interconnects of the first redistribution via layer 920-1 and the first redistribution wiring interconnect layer 924-1. For ease of illustration, the vias of the first redistribution via layer 920-1 are illustrated as having a different material than the wiring interconnects of the first redistribution wiring interconnect layer 924-1, although they may be formed using the same materials in actuality.

Redistribution wiring interconnect layers 924 within the DBR may include wiring interconnects that extend linearly and laterally and longitudinally in a plan view to connect vias of the redistribution via layers 920 within the DBR. For example, the wiring interconnects of the first redistribution wiring interconnect layer 924-1 and the second redistribution wiring interconnect layer 924-2 may be planar and extend across an array of vias in both the first horizontal direction hd1 and the second horizontal direction hd2 to electrically connect vias of the first redistribution via layer 920-1 and the second redistribution via layer 920-2. The wiring interconnects of the first redistribution wiring interconnect layer 924-1 and the second redistribution wiring interconnect layer 924-2 may be formed as planes that connect to all via within the first redistribution via layer 920-1 and the second redistribution via layer 920-2. The wiring interconnects of the first redistribution wiring interconnect layer 924-1 and the second redistribution wiring interconnect layer 924-2 may extend linearly and laterally along and extend between proximate perimeters of the first redistribution structure portion 931 and the second redistribution structure portion 932. After forming the DBR according to FIGS. 19A and 19B, the semiconductor package may be formed according to the processes described with reference to FIGS. 2A-16.

Referring to FIG. 19C, a three-dimensional expanded view of the third alternative configuration of the outlined region X of an intermediate structure after attaching a silicon bridge in FIG. 11A is illustrated. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 19C. For example, FIG. 19C illustrates the redistribution structure 918 as having one less redistribution via layer 920 and one less redistribution wiring interconnect layer 924 as compared to FIG. 11A. As another example, the width of the DBR region as illustrated in FIG. 19C appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 19C is illustrated as not including the first underfill material portion 950.

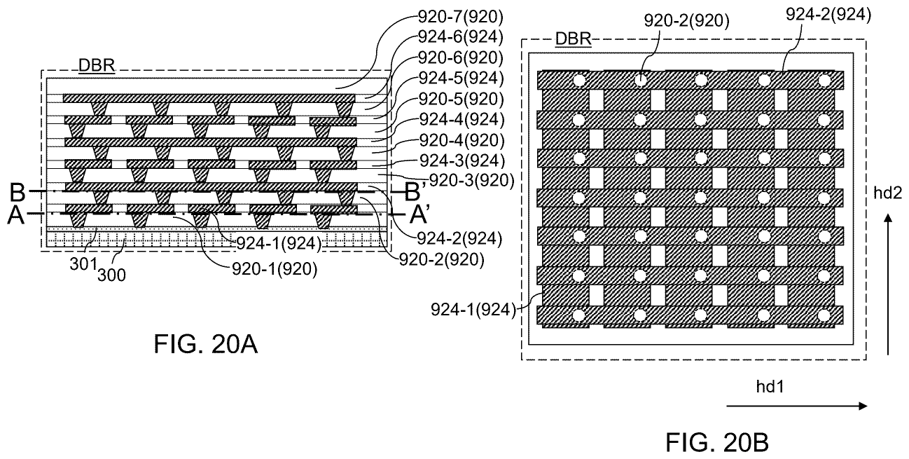

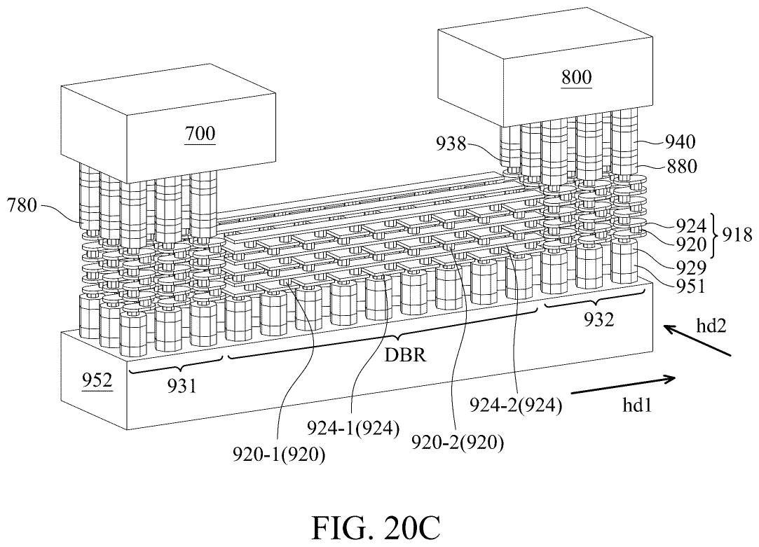

Referring to FIGS. 20A and 20B, an expanded view of a fourth alternative configuration of the DBR outlined in FIG. 1A is illustrated. The DBR as illustrated in FIGS. 20A and 20B may be formed alternatively to the DBR illustrated in FIGS. 1A-19B. The vias of the first redistribution via layer 920-1, the second redistribution via layer 920-2, and any subsequent vias of the redistribution via layers 920 may be vertically staggered with respect to a cross-sectional view, such that each next alternating via is not directly above or below the preceding or following via of the adjacent redistribution via layers 920.

FIG. 20B is a compounded top-down view of the expanded view of the DBR along the horizontal planes A-A′ and B-B′ of FIG. 20A. Referring to FIG. 20B, the top-down, or plan, view of the DBR illustrates the intersection of the vias and the wiring interconnects of the first redistribution via layer 920-1 and the first redistribution wiring interconnect layer 924-1 overlaid by the intersection of the vias and the wiring interconnects of the second redistribution via layer 920-2 and the second redistribution wiring interconnect layer 924-2. For ease of illustration, the vias are illustrated as having a different material than the wiring interconnects of the first redistribution wiring interconnect layer 924-1 and the second redistribution wiring interconnect layer 924-2, although they may be formed using the same materials in actuality. Redistribution wiring interconnect layers 924 within the DBR may include wiring interconnects that extend linearly and laterally to connect vias of the redistribution via layers 920 within the DBR. For example, the wiring interconnects of the second redistribution wiring interconnect layer 924-2 may extend linearly, laterally, and in parallel along a first horizontal direction hd1 to electrically connect vias of the second redistribution via layer 920-2. The wiring interconnects of the first redistribution wiring interconnect layer 924-1 may extend linearly, laterally, and in parallel along a second horizontal direction hd2 to electrically connect vias of the first redistribution via layer 920-1 and the second redistribution via layer 920-2. The wiring interconnects of the first redistribution wiring interconnect layer 924-1 and the second redistribution wiring interconnect layer 924-2 may be formed in rows in a striped pattern with respect to a plan view. The wiring interconnects of the first redistribution wiring interconnect layer 924-1 may extend linearly and laterally along and parallel to proximate perimeters of the first redistribution structure portion 931 and the second redistribution structure portion 932. The wiring interconnects of the second redistribution wiring interconnect layer 924-2 may extend linearly and laterally between and perpendicular to proximate perimeters of the first redistribution structure portion 931 and the second redistribution structure portion 932. The wiring interconnects of the first redistribution wiring interconnect layer 924-1 may extend perpendicular to the wiring interconnects of the second redistribution wiring interconnect layer 924-2, such that the various wiring interconnect layers within the DBR form a cross-hatch structure. After forming the DBR according to FIGS. 17A and 17B, the semiconductor package may be formed according to the processes described with reference to FIGS. 2A-16.

Referring to FIG. 20C, a three-dimensional expanded view of the fourth alternative configuration of the outlined region X of an intermediate structure after attaching a silicon bridge in FIG. 11A is illustrated. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 20C. For example, FIG. 20C illustrates the redistribution structure 918 as having one less redistribution via layer 920 and one less redistribution wiring interconnect layer 924 as compared to FIG. 11A. As another example, the width of the DBR region as illustrated in FIG. 20C appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 20C is illustrated as not including the first underfill material portion 950.

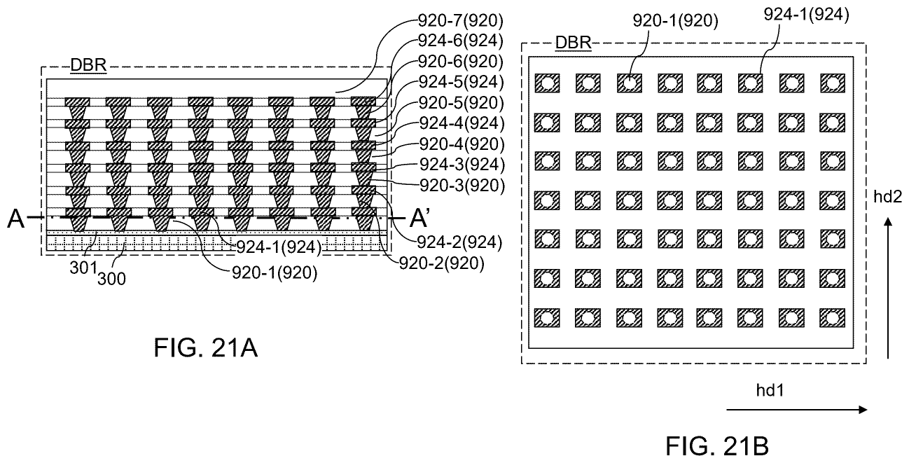

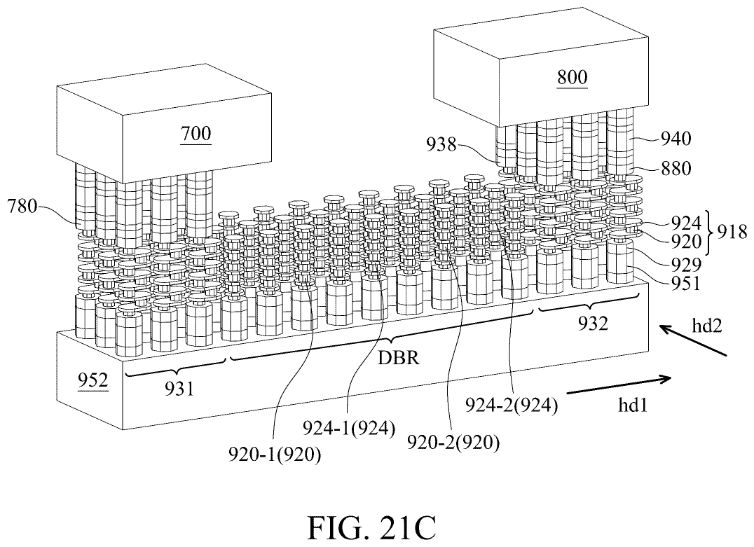

Referring to FIGS. 21A and 21B, an expanded view of a fifth alternative configuration of the DBR outlined in FIG. 1A is illustrated. The DBR as illustrated in FIGS. 21A and 21B may be formed alternatively to the DBR illustrated in FIGS. 1A-20B. The vias of the first redistribution via layer 920-1, the second redistribution via layer 920-2, and any subsequent vias of the redistribution via layers 920 may be within a same vertical plane with respect to a cross-sectional view, such that each via is directly above or below the preceding or following via of the adjacent redistribution via layers 920. The wiring interconnects may be formed and patterned in a similar manner as described with reference to FIGS. 1A-1D.

Referring to FIG. 21C, a three-dimensional expanded view of the fifth alternative configuration of the outlined region X of an intermediate structure after attaching a silicon bridge in FIG. 11A is illustrated. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 21C. For example, FIG. 21C illustrates the redistribution structure 918 as having one less redistribution via layer 920 and one less redistribution wiring interconnect layer 924 as compared to FIG. 11A. As another example, the width of the DBR region as illustrated in FIG. 21C appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 21C is illustrated as not including the first underfill material portion 950.

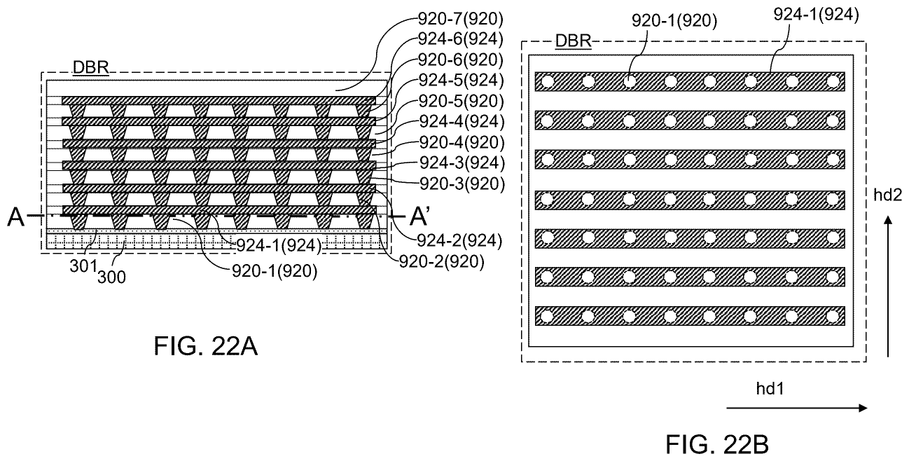

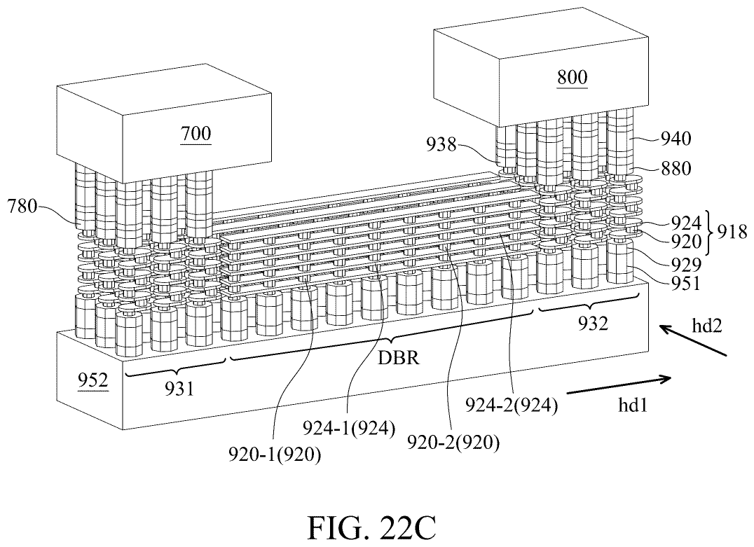

Referring to FIGS. 22A and 22B, an expanded view of a sixth alternative configuration of the DBR outlined in FIG. 1A is illustrated. The DBR as illustrated in FIGS. 22A and 22B may be formed alternatively to the DBR illustrated in FIGS. 1A-21B. The vias of the first redistribution via layer 920-1, the second redistribution via layer 920-2, and any subsequent vias of the redistribution via layers 920 may be within a same vertical plane with respect to a cross-sectional view, such that each via is directly above or below the preceding or following via of the adjacent redistribution via layers 920. The wiring interconnects may be formed and patterned in a similar manner as described with reference to FIGS. 17A-17C.

Referring to FIG. 22C, a three-dimensional expanded view of the sixth alternative configuration of the outlined region X of an intermediate structure after attaching a silicon bridge in FIG. 11A is illustrated. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 22C. For example, FIG. 22C illustrates the redistribution structure 918 as having one less redistribution via layer 920 and one less redistribution wiring interconnect layer 924 as compared to FIG. 11A. As another example, the width of the DBR region as illustrated in FIG. 22C appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 22C is illustrated as not including the first underfill material portion 950.

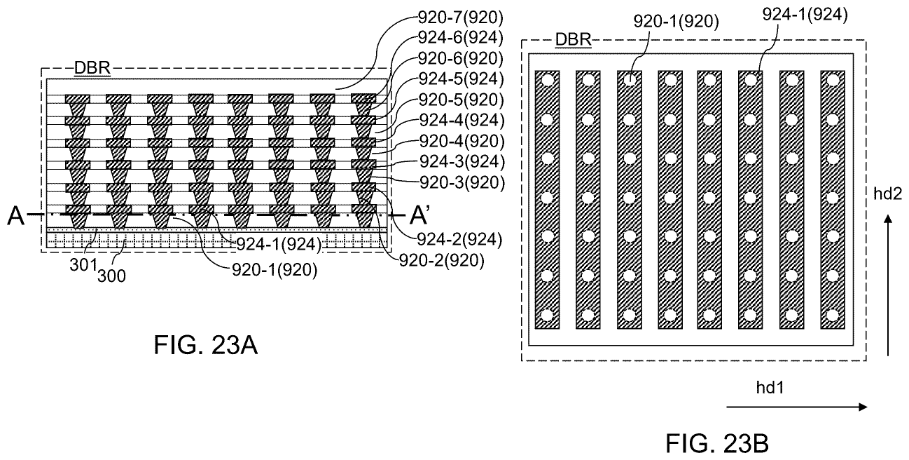

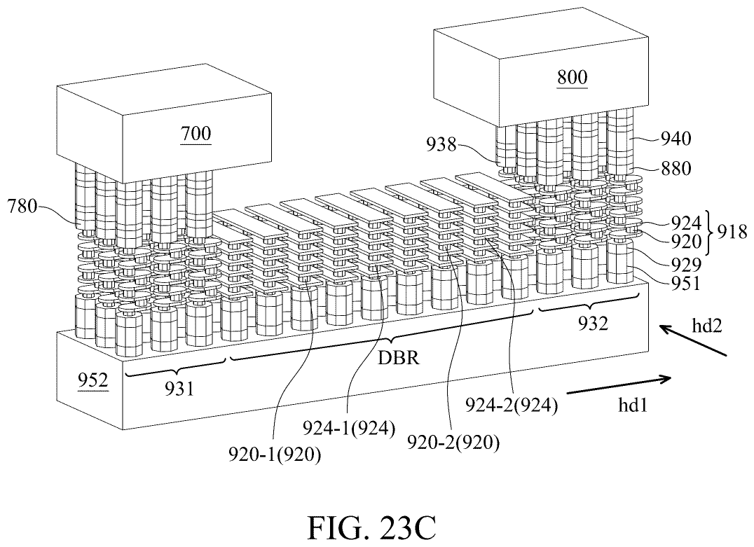

Referring to FIGS. 23A and 23B, an expanded view of a seventh alternative configuration of the DBR outlined in FIG. 1A is illustrated. The DBR as illustrated in FIGS. 23A and 23B may be formed alternatively to the DBR illustrated in FIGS. 1A-22B. The vias of the first redistribution via layer 920-1, the second redistribution via layer 920-2, and any subsequent vias of the redistribution via layers 920 may be within a same vertical plane with respect to a cross-sectional view, such that each via is directly above or below the preceding or following via of the adjacent redistribution via layers 920. The wiring interconnects may be formed and patterned in a similar manner as described with reference to FIGS. 18A-18C.

Referring to FIG. 23C, a three-dimensional expanded view of the seventh alternative configuration of the outlined region X of an intermediate structure after attaching a silicon bridge in FIG. 11A is illustrated. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 23C. For example, FIG. 23C illustrates the redistribution structure 918 as having one less redistribution via layer 920 and one less redistribution wiring interconnect layer 924 as compared to FIG. 11A. As another example, the width of the DBR region as illustrated in FIG. 23C appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 23C is illustrated as not including the first underfill material portion 950.

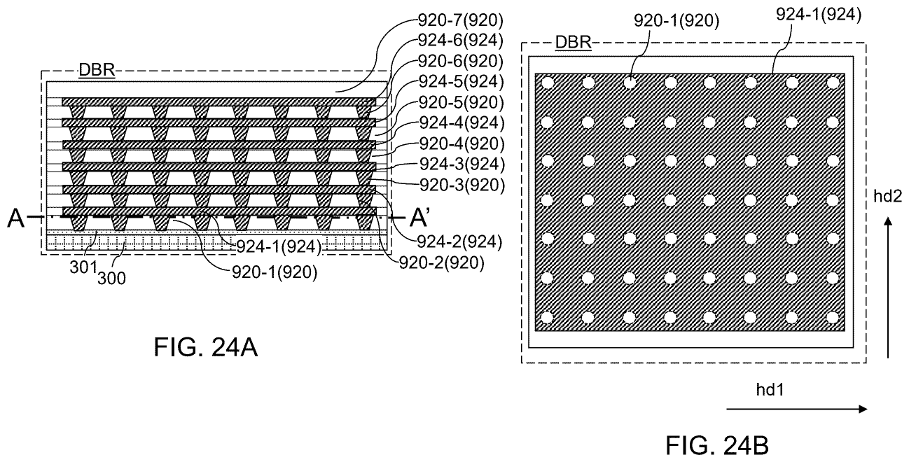

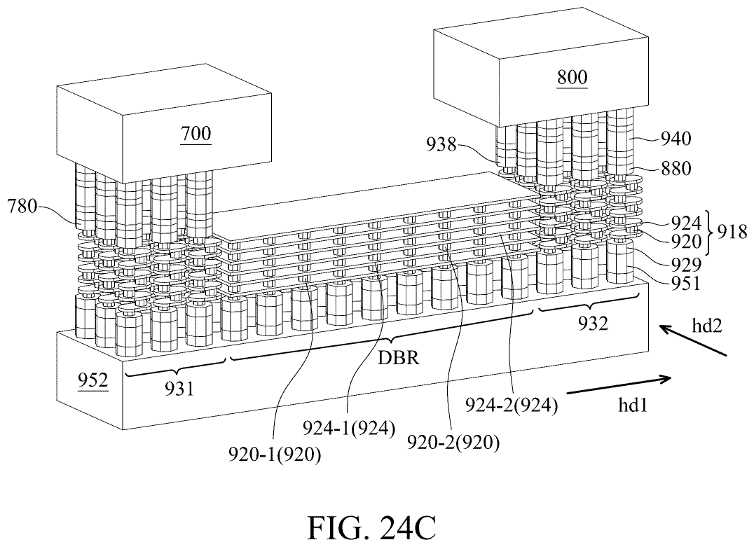

Referring to FIGS. 24A and 24B, an expanded view of an eighth alternative configuration of the DBR outlined in FIG. 1A is illustrated. The DBR as illustrated in FIGS. 24A and 24B may be formed alternatively to the DBR illustrated in FIGS. 1A-23B. The vias of the first redistribution via layer 920-1, the second redistribution via layer 920-2, and any subsequent vias of the redistribution via layers 920 may be within a same vertical plane with respect to a cross-sectional view, such that each via is directly above or below the preceding or following via of the adjacent redistribution via layers 920. The wiring interconnects may be formed and patterned in a similar manner as described with reference to FIGS. 19A-19C.

Referring to FIG. 24C, a three-dimensional expanded view of the eighth alternative configuration of the outlined region X of an intermediate structure after attaching a silicon bridge in FIG. 11A is illustrated. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 24C. For example, FIG. 24C illustrates the redistribution structure 918 as having one less redistribution via layer 920 and one less redistribution wiring interconnect layer 924 as compared to FIG. 11A. As another example, the width of the DBR region as illustrated in FIG. 24C appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 24C is illustrated as not including the first underfill material portion 950.

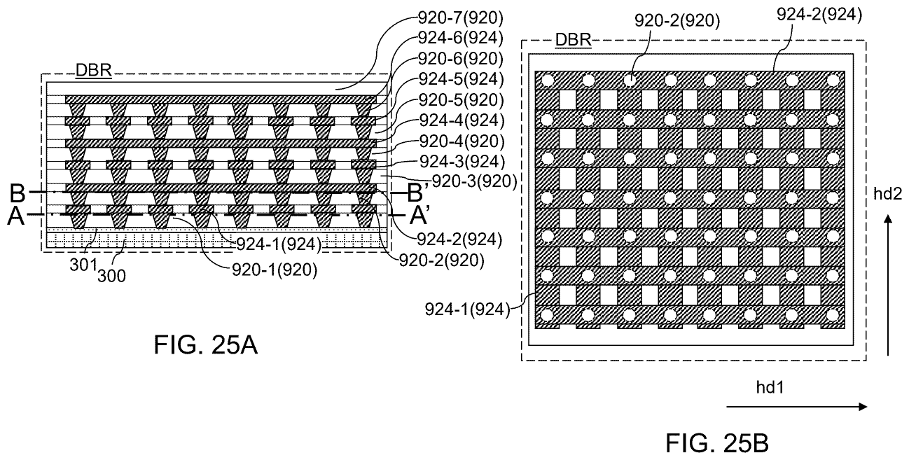

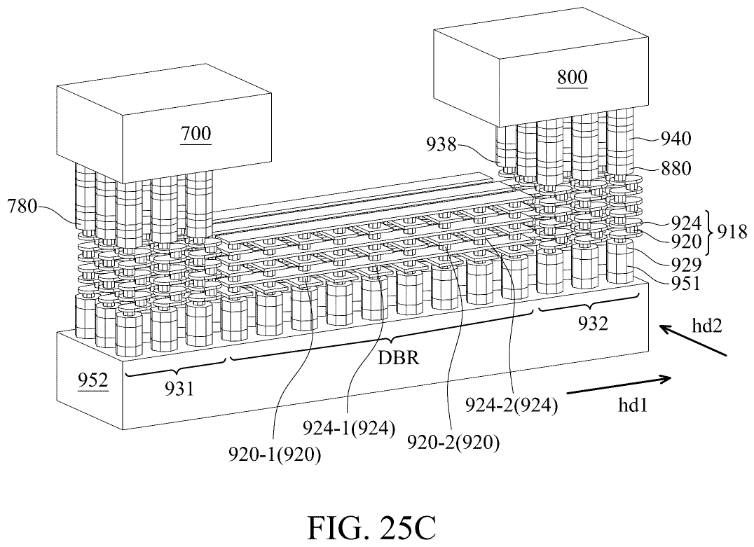

Referring to FIGS. 25A and 25B, an expanded view of a ninth alternative configuration of the DBR outlined in FIG. 1A is illustrated. The DBR as illustrated in FIGS. 25A and 25B may be formed alternatively to the DBR illustrated in FIGS. 1A-24B. The vias of the first redistribution via layer 920-1, the second redistribution via layer 920-2, and any subsequent vias of the redistribution via layers 920 may be within a same vertical plane with respect to a cross-sectional view, such that each via is directly above or below the preceding or following via of the adjacent redistribution via layers 920. The wiring interconnects may be formed and patterned in a similar manner as described with reference to FIGS. 20A-20C.

Referring to FIG. 25C, a three-dimensional expanded view of the ninth alternative configuration of the outlined region X of an intermediate structure after attaching a silicon bridge in FIG. 11A is illustrated. It is to be noted that, for ease of illustration, the number of redistribution via layers 920 and redistribution wiring interconnect layers 924 as shown in FIG. 11A is different than the number of redistribution via layers 920 and redistribution wiring interconnect layers 924 as shown in FIG. 25C. For example, FIG. 25C illustrates the redistribution structure 918 as having one less redistribution via layer 920 and one less redistribution wiring interconnect layer 924 as compared to FIG. 11A. As another example, the width of the DBR region as illustrated in FIG. 25C appears to be wider than the DBR region as illustrated in FIG. 11A. However, any number of redistribution via layers 920 and redistribution wiring interconnect layers 924 and any size of the DBR region may be implemented throughout the redistribution structure 918. Additionally, for ease of illustration, FIG. 25C is illustrated as not including the first underfill material portion 950.

By forming the DBR within the redistribution structure 918 between the first redistribution structure portion 931 and the second redistribution structure portion 932, the reliability window may be improved such that the deformation of signal redistribution layout (i.e., redistribution via layers 920 and redistribution wiring interconnect layers 924 of the first redistribution structure portion 931 and the second redistribution structure portion 932) can be suppressed and strain is reduced. Thus, the various embodiments may reduce deformation of signal-carrying wiring interconnects of the redistribution structure 918 caused by CTE mismatches and material expansion and contraction.

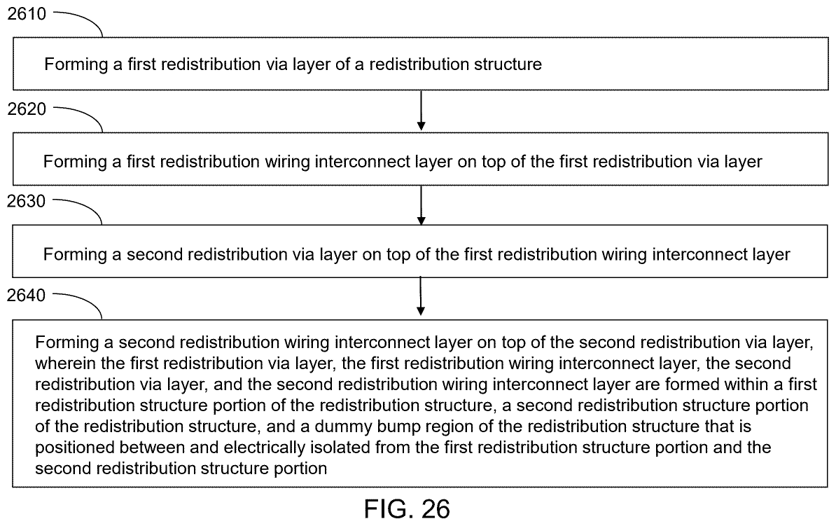

Referring to FIG. 26, a flowchart illustrates steps for forming an exemplary structure according to an embodiment of the present disclosure.

Referring to step 2610 and FIGS. 1A-1D, a first redistribution via layer of a redistribution structure 918 may be formed.

Referring to step 2620 and FIGS. 1A-1D, a first redistribution wiring interconnect layer may be formed on top of the first redistribution via layer.

Referring to step 2630 and FIGS. 1A-1D, a second redistribution via layer may be formed on top of the first redistribution wiring interconnect layer.

Referring to step 2640 and FIGS. 1A-1D, a second redistribution wiring interconnect layer may be formed on top of the second redistribution via layer, in which the first redistribution via layer, the first redistribution wiring interconnect layer, the second redistribution via layer, and the second redistribution wiring interconnect layer are formed within a first redistribution structure portion of the redistribution structure, a second redistribution structure portion of the redistribution structure, and a dummy bump region of the redistribution structure that is positioned between and electrically isolated from the first redistribution structure portion and the second redistribution structure portion.

The first redistribution via layer, the first redistribution wiring interconnect layer, the second redistribution via layer, and the second redistribution wiring interconnect layer may be formed within a first redistribution structure portion 931 of the redistribution structure 918, a second redistribution structure portion 932 of the redistribution structure 918, and a dummy bump region DBR of the redistribution structure 918 that is positioned between and electrically isolated from the first redistribution structure portion 931 and the second redistribution structure portion 932.

In some embodiments, the method for forming an exemplary structure may further include attaching a first semiconductor die (e.g., semiconductor dies (700, 800)) to the first redistribution structure portion 931, and attaching a second semiconductor die (e.g., semiconductor die (700, 800)) to the second redistribution structure portion 932, in which portions of the dummy bump region are positioned in a same vertical plane as at least one of the first semiconductor die (e.g., semiconductor die (700, 800)) and the second semiconductor die (e.g., semiconductor die (700, 800)).

In some embodiments, the method for forming an exemplary structure may further include attaching a silicon bridge 952 to the first redistribution via layer 920-1 of the dummy bump region, the first redistribution structure portion 931, and the second redistribution structure portion 932 to electrically connect the first semiconductor die (e.g., semiconductor die (700, 800)) and the second semiconductor die (e.g., semiconductor die (700, 800)).

In some embodiments, forming the first redistribution wiring interconnect layer 924-1 on top of the first redistribution via layer 920-1 may include forming wiring interconnect structures within the dummy bump region to laterally connect vias of the first redistribution via layer 920-1 and the second redistribution via layer 920-2, and forming the second redistribution wiring interconnect layer 924-2 on top of the second redistribution via layer 920-2 may include forming wiring interconnect structures within the dummy bump region to laterally connect vias of the second redistribution via layer 920-2. In some embodiments, wiring interconnect structures of the first redistribution wiring interconnect layer 924-1 within the dummy bump region may be formed in parallel, and wiring interconnect structures of the second redistribution wiring interconnect layer 924-2 within the dummy bump region may be formed in parallel.

In some embodiments, forming the first redistribution wiring interconnect layer 924-1 on top of the first redistribution via layer 920-1 may include forming a planar wiring interconnect structure to connect all vias of the first redistribution via layer 920-1 and all vias of the second redistribution via layer 920-2 within the dummy bump region, and forming the second redistribution wiring interconnect layer 924-2 on top of the second redistribution via layer 920-2 may include forming a planar wiring interconnect structure to connect all vias of the second redistribution via layer 920-2 within the dummy bump region.

Referring to all drawings and according to various embodiments of the present disclosure, a chip package structure is provided, which may include: a first semiconductor die (e.g., semiconductor die (700, 800)); a second semiconductor die (e.g., semiconductor die (700, 800)); a redistribution structure 918 including: a first redistribution structure portion 931 physically and electrically connected to the first semiconductor die (e.g., semiconductor die (700, 800)); a second redistribution structure portion 932 physically and electrically connected to the second semiconductor die (e.g., semiconductor die (700, 800)); and a dummy bump region positioned between and electrically isolated from the first redistribution structure portion 931 and the second redistribution structure portion 932; and a first underfill material portion 950 located between the redistribution structure 918 and the first semiconductor die (e.g., semiconductor die (700, 800)) and the second semiconductor die (e.g., semiconductor die (700, 800)).

In some embodiments, the dummy bump region may include: a first redistribution via layer 920-1; a first redistribution wiring interconnect layer 924-1 physically and electrically connected to the first redistribution via layer 920-1; a second redistribution via layer 920-2 physically and electrically connected to the first redistribution wiring interconnect layer 924-1; and a second redistribution wiring interconnect layer 924-2 physically and electrically connected to the second redistribution via layer 920-2.

In some embodiments, vias formed in the first redistribution via layer 920-1 and vias formed in the second redistribution via layer 920-2 are staggered such that the vias formed in the second redistribution via layer 920-2 are offset along a first horizontal direction from vias formed in the first redistribution via layer 920-1. In some embodiments, vias of the second redistribution via layer 920-2 may be directly above vias of the first redistribution via layer 920-1 in a cross-sectional view.

In some embodiments, the first redistribution via layer 920-1, the first redistribution wiring interconnect layer 924-1, the second redistribution via layer 920-2, and the second redistribution wiring interconnect layer 924-2 may be formed to have an array of electrically isolated columns with each column including one via of the first redistribution via layer 920-1, one wiring interconnect of the first redistribution wiring interconnect layer 924-1, one via of the second redistribution via layer 920-2, and one wiring interconnect of the second redistribution wiring interconnect layer 924-2.

In some embodiments, wiring interconnects of the first redistribution wiring interconnect layer 924-1 may extend horizontally to electrically connect vias of the first redistribution via layer 920-1, wiring interconnects of the first redistribution wiring interconnect layer 924-1 may be positioned parallel to each other in a striped pattern, wiring interconnects of the second redistribution wiring interconnect layer 924-2 may extend horizontally to electrically connect vias of the second redistribution via layer 920-2, and wiring interconnects of the second redistribution wiring interconnect layer 924-2 may be positioned parallel to each other in a striped pattern.

In some embodiments, the wiring interconnects of the first redistribution wiring interconnect layer 924-1 may be parallel to the wiring interconnects of the second redistribution wiring interconnect layer 924-2, and wiring interconnects of the first redistribution wiring interconnect layer 924-1 and the second redistribution wiring interconnect layer 924-2 may extend parallel to proximate perimeters of the first redistribution structure portion 931 and the second redistribution structure portion 932.

In some embodiments, the wiring interconnects of the first redistribution wiring interconnect layer 924-1 may extend parallel to the wiring interconnects of the second redistribution wiring interconnect layer 924-2, and wiring interconnects of the first redistribution wiring interconnect layer 924-1 and the second redistribution wiring interconnect layer 924-2 may extend perpendicular to proximate perimeters of the first redistribution structure portion 931 and the second redistribution structure portion 932.

In some embodiments, the wiring interconnects of the first redistribution wiring interconnect layer 924-1 may extend perpendicular to wiring interconnects of the second redistribution wiring interconnect layer 924-2.

In some embodiments, the first redistribution wiring interconnect layer 924-1 may include a planar wiring interconnect physically and electrically connected to all vias within the first redistribution via layer 920-1, and a second redistribution wiring interconnect layer 924-2 may include a planar wiring interconnect physically and electrically connected to all vias within the second redistribution via layer 920-2.

In some embodiments, a density of vias within the dummy bump region may be defined as a total area of vias within a horizontal plane in a plan view divided by the total area of vias and the total area of dielectric material within the horizontal plane in a plan view, and the density of vias may be at least 3%.

In some embodiments, the chip package may further include a silicon bridge 952 that electrically connects the first semiconductor die (e.g., semiconductor die (700, 800)) to the second semiconductor die (e.g., semiconductor die (700, 800)) through the first redistribution structure portion 931 and the second redistribution structure portion 932, in which the first redistribution via layer 920-1 is connected to the silicon bridge.

In some embodiments, portions of the dummy bump region may be positioned in a same vertical plane as at least one of the first semiconductor die (e.g., semiconductor die (700, 800)) and the second semiconductor die (e.g., semiconductor die (700, 800)) in a vertical cross-sectional view.

Referring to all drawings and according to various embodiments of the present disclosure, a redistribution structure 918 for use in a chip package structure is provided, which may include: a first redistribution structure portion 931; a second redistribution structure portion 932; and a dummy bump region positioned between the first redistribution structure portion 931 and the second redistribution structure portion 932, the dummy bump region including: at least one redistribution wiring interconnect layer (e.g., first redistribution wiring interconnect layer 924-1, second redistribution wiring interconnect layer 924-2); and at least two redistribution via layers (e.g., first redistribution via layer 920-1, second redistribution via layer 920-2) connected to the at least one redistribution wiring interconnect layer, in which the number of the redistribution via layers is one more than the number of redistribution wiring interconnect layers.

In some embodiments, vias of the at least two redistribution via layers may be enhanced vias.

The various structures and methods of the present disclosure may be used to provide a chip package structure including a fan-out package 900 including at least one cut region CR, which reduces mechanical coupling between the fan-out package 900 and the package substrate 200, and reduces distortion of the fan-out package 900 under mechanical and/or thermal stress. The chip package structure of the present disclosure provides a configuration that avoids formation of a stress concentration points from which cracks in a molding compound material portion may initiate under mechanical stress during handling of the chip package structure or during use of a device including the chip package structure. The various methods and structures of the present disclosure may be used to reduce deformation of a fan-out package 900 and to increase the reliability of the fan-out package 900.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a chip package structure, comprising:
forming a first redistribution via layer of a redistribution structure;
forming a first redistribution wiring interconnect layer on top of the first redistribution via layer;
forming a second redistribution via layer on top of the first redistribution wiring interconnect layer; and
forming a second redistribution wiring interconnect layer on top of the second redistribution via layer,
wherein the first redistribution via layer, the first redistribution wiring interconnect layer, the second redistribution via layer, and the second redistribution wiring interconnect layer are formed within a first redistribution structure portion of the redistribution structure, a second redistribution structure portion of the redistribution structure, and a dummy bump region of the redistribution structure that is positioned between and electrically isolated from the first redistribution structure portion and the second redistribution structure portion.

2. The method of claim 1, further comprising:
attaching a first semiconductor die to the first redistribution structure portion; and
attaching a second semiconductor die to the second redistribution structure portion, wherein portions of the dummy bump region are positioned in a same vertical plane as at least one of the first semiconductor die and the second semiconductor die in a vertical cross-sectional view.

3. The method of claim 2, further comprising:
attaching a silicon bridge to the first redistribution via layer of the dummy bump region, the first redistribution structure portion, and the second redistribution structure portion to electrically connect the first semiconductor die and the second semiconductor die.

4. The method of claim 1, wherein:
forming the first redistribution wiring interconnect layer on top of the first redistribution via layer comprises forming wiring interconnect structures within the dummy bump region to laterally connect vias of the first redistribution via layer and the second redistribution via layer,
forming the second redistribution wiring interconnect layer on top of the second redistribution via layer comprises forming wiring interconnect structures within the dummy bump region to laterally connect vias of the second redistribution via layer,
wiring interconnect structures of the first redistribution wiring interconnect layer within the dummy bump region are formed in parallel, and
wiring interconnect structures of the second redistribution wiring interconnect layer within the dummy bump region are formed in parallel.

5. The method of claim 1, wherein:
forming the first redistribution wiring interconnect layer on top of the first redistribution via layer comprises forming a planar wiring interconnect structure to connect all vias of the first redistribution via layer and all vias of the second redistribution via layer within the dummy bump region, and
forming the second redistribution wiring interconnect layer on top of the second redistribution via layer comprises forming a planar wiring interconnect structure to connect all vias of the second redistribution via layer within the dummy bump region.

6. A method of forming a chip package structure, comprising:
forming a multi-layered redistribution structure on a carrier substrate, the multi-layered redistribution structure including:
a first redistribution structure portion configured for electrical connection to a first semiconductor die;
a second redistribution structure portion configured for electrical connection to a second semiconductor die; and
a dummy bump region positioned between the first redistribution structure portion and the second redistribution structure portion;
wherein forming the multi-layered redistribution structure includes concurrently forming a plurality of redistribution via layers and a plurality of redistribution wiring interconnect layers within the dummy bump region such that the dummy bump region is electrically isolated from the first redistribution structure portion and the second redistribution structure portion.

7. The method of claim 6, further comprising:
attaching a first semiconductor die to the first redistribution structure portion; and
attaching a second semiconductor die to the second redistribution structure portion, wherein portions of the dummy bump region are positioned in a same vertical plane as at least one of the first semiconductor die and the second semiconductor die in a vertical cross-sectional view.

8. The method of claim 7, further comprising:
attaching a silicon bridge to a first redistribution via layer of the dummy bump region, the first redistribution structure portion, and the second redistribution structure portion to electrically connect the first semiconductor die and the second semiconductor die.

9. The method of claim 6, wherein forming the plurality of redistribution wiring interconnect layers includes forming wiring interconnect structures within the dummy bump region to laterally connect vias of adjacent redistribution via layers.

10. The method of claim 6, wherein vias formed in adjacent redistribution via layers within the dummy bump region are staggered such that vias in an upper layer are offset along a first horizontal direction from vias in a lower layer.

11. The method of claim 6, wherein forming the plurality of redistribution wiring interconnect layers comprises forming wiring interconnects that extend linearly in a first horizontal direction and are positioned parallel to each other in a striped pattern within the dummy bump region.

12. The method of claim 6, wherein forming the plurality of redistribution wiring interconnect layers comprises forming wiring interconnects that extend linearly in a second horizontal direction and are positioned parallel to each other in a striped pattern within the dummy bump region.

13. The method of claim 6, wherein forming the plurality of redistribution via layers and the plurality of redistribution wiring interconnect layers comprises:
depositing a metallic seed layer by sputtering;
applying and patterning a photoresist layer over the metallic seed layer to form a pattern of openings; and
electroplating a metallic fill material through the openings.

14. A method of enhancing reliability of a chip package structure, comprising:
providing a redistribution structure having a first redistribution structure portion and a second redistribution structure portion;
forming a dummy bump region within the redistribution structure between the first redistribution structure portion and the second redistribution structure portion, wherein the dummy bump region is electrically isolated from the first redistribution structure portion and the second redistribution structure portion; and
forming a plurality of enhanced vias and a plurality of enhanced wiring interconnects within the dummy bump region to suppress deformation of signal redistribution layout in the first redistribution structure portion and the second redistribution structure portion and to reduce strain caused by coefficient of thermal expansion mismatches.

15. The method of claim 14, wherein the plurality of enhanced vias within the dummy bump region are formed such that a density of enhanced vias within a horizontal plane in a plan view is at least 3%, where the density of enhanced vias is defined as a total area of vias divided by the total area of vias and a total area of dielectric material within the horizontal plane.

16. The method of claim 14, wherein the plurality of enhanced vias formed in adjacent redistribution via layers within the dummy bump region are staggered such that the plurality of enhanced vias in an upper layer are offset along a first horizontal direction from the plurality of enhanced vias in a lower layer.

17. The method of claim 14, wherein forming the plurality of enhanced wiring interconnects comprises forming wiring interconnects that extend linearly in a first horizontal direction and are positioned parallel to each other in a striped pattern within the dummy bump region.

18. The method of claim 14, wherein forming the dummy bump region comprises:
forming a plurality of redistribution via layers and a plurality of redistribution wiring interconnect layers by:
depositing a metallic seed layer by sputtering;
applying and patterning a photoresist layer over the metallic seed layer to form a pattern of openings; and
electroplating a metallic fill material through the openings.

19. The method of claim 14, further comprising:
attaching a first semiconductor die to the first redistribution structure portion; and
attaching a second semiconductor die to the second redistribution structure portion, wherein portions of the dummy bump region are positioned in a same vertical plane as at least one of the first semiconductor die and the second semiconductor die in a vertical cross-sectional view.

20. The method of claim 19, further comprising:
forming a first underfill material portion by applying an underfill material into a gap between the redistribution structure and the first semiconductor die and the second semiconductor die; and
applying an epoxy molding compound to form an EMC matrix that laterally surrounds and embeds the first semiconductor die, the second semiconductor die, and the first underfill material portion.
